(19) United States
(12) Patent Application Publication
(10) Pub. No.: US 2023/0121670 A1
(43) Pub. Date: Apr. 20, 2023

(54) HIGH CAPACITY CATHODES FOR ALL-SOLID-STATE THIN-FILM BATTERIES

(71) Applicants: NANOEAR CORPORATION, INC., Houston, TX (US); University of Rochester, Rochester, NY (US)

(72) Inventors: Fei HU, Rochester, NY (US); Wyatt E. TENHAEFF, Pittsford, NY (US); William Clark WEST, South Pasadena, CA (US)

(21) Appl. No.: 17/964,746

(22) Filed: Oct. 12, 2022

Related U.S. Application Data
(60) Provisional application No. 63/255,814, filed on Oct. 14, 2021.

(51) Int. Cl. H01M 4/131; H01M 4/485; H01M 4/1391; H01M 4/04; H01M 4/66; H01M 10/0585; C23C 14/08; C23C 14/34

(52) U.S. Cl. CPC H01M 4/131; H01M 4/485; H01M 4/1391; H01M 4/0426; H01M 4/0404; H01M 4/661; H01M 10/0585; C23C 14/085; C23C 14/34; H01M 2004/028

(57) ABSTRACT

A method is described herein for forming a high-capacity thin-film battery. The thin-film battery utilizes a cathode containing each of lithium, ruthenium, cobalt, and oxygen. The cathode composition is synthesized as a solution of LiRu₂O₃ and LiCoO₂ and deposited on a substrate using a physical vapor deposition sputtering technique. The cathode is then covered by an electrolyte and an anode to form a thin film battery. The cathode within the resulting thin film battery may be as-deposited and without being annealed to have an amorphous composition, or the cathode may be annealed after depositing the cathode.

### CROSS-REFERENCE TO RELATED APPLICATIONS

This application claims priority to the U.S. Provisional Patent Application Ser. No. 63/255,814, filed Oct. 14, 2021, which is incorporated herein by reference in its entirety.

### BACKGROUND

### Field

Embodiments described herein generally relate to energy storage devices and methods of forming energy storage devices. More specifically, the energy storage device is a solid-state lithium thin-film battery.

### Description of the Related Art

Solid-state lithium thin-film batteries are utilized to enable enhanced energy storage performance, improved cycle life, enhanced safety, and high specific energies. The current approach to fabricating thin film batteries (TFBs) utilizes a series of vacuum deposition operations to deposit the cell components on a macroscopically thick substrate. Examples of these techniques include thermal evaporation, sputtering, chemical vapor deposition, pulsed laser deposition, and related approaches. TFBs are utilized for applications within smart sensors, micro-computers, biomedical health devices, tiny robots, etc.

TFBs are currently limited in overall energy density. Therefore, thin-film cathode materials with higher specific energy are needed. The specific energy of the thin-film cathodes largely determine the overall energy density of the cell. For the cathode side, many polycrystalline, inorganic cathode compounds have been developed, but have limited specific energy or poor charge reversibility. Further, polycrystalline thin film cathodes typically require high temperature annealing to achieve the preferred crystalline phase and optimal energy storage performance. High temperature annealing adds significant processing time and additional cost, while limiting material compatibility of the substrate.

Therefore, what is needed are cathode materials with higher specific capacities and reduced processing requirements.

### SUMMARY

The present inventors have developed novel cathode materials that can be employed in a variety of lithium thin-film battery applications. The novel cathode materials are based on lithium, ruthenium, cobalt, and oxides thereof, and provide energy densities that are equal to or greater than current cathode materials. Additionally, the novel cathode materials can be prepared in the absence of a thermal annealing step. By forgoing the high temperature conditions required for thermal annealing, the cathode materials disclosed herein can be assembled on a wide variety of substrates, including lower melt-temperature, flexible thermoplastic materials.

The present disclosure is generally directed towards energy storage devices and methods of forming energy storage devices. In one embodiment, an energy storage device is described. The energy storage device includes a cathode, an anode, and an electrolyte. The cathode includes lithium, ruthenium, cobalt, and oxygen. The anode is disposed adjacent to the cathode. The electrolyte is disposed between the cathode and the anode.

In another embodiment, an energy storage device is described which includes a support substrate, a platinum film disposed on a portion of the support substrate, a cathode disposed on the platinum film, an anode disposed adjacent to the cathode, and an electrolyte disposed between the cathode and the anode. The cathode includes lithium, ruthenium, cobalt, and oxygen. The anode includes lithium. In some embodiments, the cathode includes a cathode material with amounts of lithium, ruthenium, cobalt, and oxygen based on the formula Li₂₊ₓRu₁₋ₓCoₓO₃, where x is 0.1, 0.2, or 0.3. In some aspects, in the formula Li₂₊ₓRu₁₋ₓCoₓO₃, x is any one of, less than, greater than, between, or any range thereof of 0.1, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, and 0.30. In some embodiments, the cathode includes a cathode material with amounts of lithium, ruthenium, cobalt, and oxygen based on the formula (1−x)Li₂RuO₃+xLiCoO₂+yLi₂O) where y ranges from 0.05 to 0.6 and x ranges from 0.05 to 0.5. In some embodiments, in the formula (1−x)Li₂RuO₃+xLiCoO₂+yLi₂O), y is any one of, less than, greater than, between, or any range thereof of 0.05, 0.06, 0.07, 0.08, 0.09, 0.10, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, 0.30, 0.31, 0.32, 0.33, 0.34, 0.35, 0.36, 0.37, 0.38, 0.39, 0.40, 0.41, 0.42, 0.43, 0.44, 0.45, 0.46, 0.47, 0.48, 0.49, 0.50, 0.51, 0.52, 0.53, 0.54, 0.55, 0.56, 0.57, 0.58, 0.59, and 0.60. In some embodiments, in the formula (1−x)Li₂RuO₃+xLiCoO₂+yLi₂O), x is any one of, less than, greater than, between, or any range thereof of 0.05, 0.06, 0.07, 0.08, 0.09, 0.10, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, 0.30, 0.31, 0.32, 0.33, 0.34, 0.35, 0.36, 0.37, 0.38, 0.39, 0.40, 0.41, 0.42, 0.43, 0.44, 0.45, 0.46, 0.47, 0.48, 0.49, and 0.50.

In yet another embodiment, a method of forming an energy storage device is described. The method includes depositing a cathode film onto a support substrate within a process volume of a processing chamber, depositing an electrolyte over the cathode layer, and depositing an anode over the electrolyte. The deposited cathode layer includes lithium, ruthenium, cobalt, and oxygen.

In yet another embodiment, an energy storage device is described. The energy storage device includes a cathode comprising lithium, oxygen, and two or more metals. The two or more metals are selected from a group of ruthenium, cobalt, tin, iridium, and manganese. The energy storage device further includes an anode disposed adjacent to the cathode and an electrolyte disposed between the cathode and the anode.

In yet another embodiment, a method of forming an energy storage device is described. The method includes depositing a cathode film onto a support substrate within a process volume of a processing chamber, depositing an electrolyte over the cathode film, and depositing an anode over the electrolyte. The cathode film includes lithium, oxygen, and at least two of ruthenium, cobalt, tin, iridium, and manganese.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a thin-film battery, according to embodiments described herein.

FIG. 2 is a schematic cross-sectional view of a process chamber for depositing one or more films, according to embodiments described herein.

FIG. 3 illustrates a method of forming the thin-film battery of FIG. 1, according to embodiments described herein.

FIGS. 4A-4B are graphs illustrating x-ray diffraction patterns of a cathode synthesized at different temperatures.

FIGS. 5A-5B are scanning electron microscope images of a cathode material powder.

FIGS. 6A-6C are graphs illustrating charge and discharge curves of assembled lithium ion half cells with an LRCO cathode material after synthesizing the LRCO cathode material at various calcination temperatures.

FIGS. 7A-7C are graphs illustrating cycling stability curves of the assembled lithium ion half cells with the LRCO cathode material after synthesizing the LRCO cathode material at the various calcination temperatures.

FIGS. 8A-8B are graphs illustrating x-ray diffraction patterns of a cathode synthesized with varying cobalt contents.

FIGS. 9A-9B are graphs illustrating charge and discharge curves of assembled lithium ion half cells with an LRCO cathode material after synthesizing the LRCO cathode material with varying cobalt contents.

FIGS. 10A-10B are graphs illustrating cycling stability curves of the assembled lithium ion half cells with the LRCO cathode material after synthesizing the LRCO cathode material with varying cobalt contents.

FIGS. 11A-11D are graphs illustrating x-ray photoelectron spectroscopy measurements of a film deposited from a sputtering target formed from the LRCO material.

FIGS. 12A-12F illustrate plan-view scanning electron micrographs of thin films deposited from a sputtering target formed from the LRCO material after various annealing operations.

FIG. 13 includes x-ray diffraction patterns of a cathode which is annealed at various anneal temperatures.

FIGS. 14A-14D illustrate scanning electron micrographs of annealed thin films deposited from a sputtering target formed from the LRCO material.

FIG. 15 is a graph illustrating charge and discharge curves of assembled lithium ion half cells with an LRCO cathode material after cycling using a first charging pattern.

FIGS. 16 is a graph illustrating cycling stability curves of the assembled lithium ion half cells with the LRCO cathode material after cycling using the first charging pattern.

FIGS. 17A-17C are graphs of charge/discharge voltage profiles of LRCO thin film batteries from 2.0 V to 3.8, 3.9, and 4.0V, respectively, at 0.3C for the 1st, 50th and 100th cycle.

FIGS. 18A-18C are graphs of discharge capacity/coulombic efficiency of LRCO thin film batteries from 2.0 V to 3.8, 3.9, and 4.0V, respectively, over a given number of cycles.

FIG. 19 is a rate performance graph of LRCO/LCO thin film batteries with 300 nm-thick cathodes at 3, 10, 15, 27, 33, then back to 3 μA/cm². Cycling parameters: 2.0-3.9 V (LRCO) and 3.0-4.2 V (LCO) vs. Li/Li+ at 25° C.

FIGS. 20A-20B are graphs illustrating charge and discharge curves of assembled lithium thin film cells with an LRCO cathode material after annealing the first cathode material at various temperatures.

FIGS. 21A-21B are graphs illustrating cycling stability curves of the assembled lithium thin film cells with the LRCO cathode material after annealing the first cathode material at various temperatures.

FIG. 22 is a schematic illustration of the thin film battery fabrication process.

FIGS. 23A-23B are schematic illustrations and plan-view scanning electron micrograph (SEM) images of LRCO thin-films on Si wafers comparing the deposited film morphologies for sputtering target-to-substrate distances.

FIGS. 24A-24B are plan view and cross-sectional SEM images of as-deposited LRCO thin films on a Si wafer with a thermal oxide at a sputtering distance of 5 cm.

FIG. 25 is a graph of XRD patterns comparing an LRCO sputtering target, as-deposited LRCO thin films, and a thermal oxide Si wafer substrate.

FIG. 26 is a cross-sectional SEM image of as-deposited LRCO thin films on a Si wafer (deposition distance was 10 cm).

FIG. 27 is a graph depicting EDS spectrum and corresponding elemental composition of as-deposited LRCO thin films on a Si wafer with a thermal oxide at a sputtering distance of 10 cm.

FIG. 28 is a 3D schematic structure of an LRCO thin-film battery.

FIGS. 29A-29D are cross-sectional SEM views of completed thin film batteries with a 300 nm-thick LRCO cathode, presented with corresponding elemental EDS maps of P, Ru and Si, respectively.

FIG. 30 is a digital image of two completed thin film batteries on a quartz slide.

FIG. 31 is a graph of differential capacity vs. voltage of 300 nm-thick as-deposited LRCO thin film batteries for the charge step at second cycle from 2.0-4.0 V at 10 μA/cm² (0.3 C).

FIGS. 32A-32B are graphs of cycling performance of a LRCO thin film batteries with 300 nm-thick as-deposited cathode from 2.0-3.9 V at 10 μA/cm² (0.3 C) for over 300 cycles and of a cycling performance comparison between three LRCO thin film batteries cycled from 2.0-4.0 Vat 10 μA/cm² (0.3 C).

FIGS. 33A-33B are a cyclic voltammogram graph of LCO thin film batteries with 300 nm-thick as-deposited cathodes at a scan rate of 0.1 mV/s from 3.0-4.2 V and a differential capacity vs. voltage graph of as-deposited LCO thin film batteries for the charge step at second cycle from 3.0-4.2 V at 10 μA/cm².

FIG. 34 is cyclic voltammogram graph of LRCO/LCO thin film batteries with 300 nm-thick as-deposited cathodes at a scan rate of 0.1 mV/s and voltage range of 2.0-3.9 V vs. Li/Li⁺.

FIG. 35 is cycling performance graph of LCO thin film batteries with 300 nm-thick as-deposited cathodes cycled from 3.0-4.2 Vat 10 μA/cm².

FIG. 36 is a graph comparing typical inorganic thin-film cathode candidates, including specific capacity, capacity retention after specific cycle numbers and annealing temperature for cathodes (RT=room temperature).

FIG. 37 is a graph depicting open-circuit voltage of Kapton®-based LRCO thin film batteries under bending for the first five minutes and under rest (flat) for the remaining five minutes.

FIGS. 38A-38B are graphs depicting cycling performance of LRCO thin film batteries with 300 nm-thick as-deposited cathodes on a bent PET substrate over 120 cycles, and on a Kapton substrate which remained flat for the 60 cycles and was then bent for the remaining 60 cycles.

FIGS. 39A-39B are images of a flexible LRCO TFB on a PET substrate operating a LED before and after bending, respectively.

FIG. 40 is a graph comparing typical inorganic thin-film cathode candidates on flexible substrates, including specific capacity, capacity retention after 100 cycle numbers and annealing temperature for cathodes. Capacity retentions of LiMnO₄ (700° C.), LiNi_{0.5}Mn_{1.5}O₄ (RT) and Li₄Ti₅O₁₂ (230° C.) are reported at the 80th, 20th and 90th cycles, respectively.

FIG. 41 includes a table comparing properties of various thin-film cathode materials.

FIG. 42 includes a table comparing various thin-film cathodes on flexible substrates.

### DETAILED DESCRIPTION

Embodiments of the present disclosure are directed towards a high-capacity thin-film cathode for solid-state lithium thin film batteries. In some embodiments, the solid-state lithium thin film batteries are fabricated with sub-millimeter dimensions, such as on the order of 100 μm×100 μm. In some embodiments, the solid-state lithium thin film batteries are from a few micrometers to tens of micrometers thick, such as about 5 μm to about 30 μm thick, such as about 5 μm to about 20 μm thick, such as about 5 μm to about 15 μm thick. The cathode composition is synthesized as a solid solution of LiRu₂O₃ and LiCoO₂ and contains lithium, ruthenium, cobalt, and oxygen. The thin-film cathode is fabricated on a substrate by radio-frequency magnetron sputtering techniques and the as-deposited thin-film cathode has roughly two times the discharge capacity of current thin-film cathodes, such as LiCoO₂. The cathode is also shown to be fully functional and reversible in the as-deposited, un-annealed state.

The cathode composition may roughly have a nominal composition of (1−x)Li₂RuO₃+xLiCoO₂+yLi₂O. In embodiments wherein y is the same as x, the formula is shown as Li₂₊ₓRu₁₋ₓCoₓO₃. As described herein, y may be varied between about 0.05 to about 0.6, such as about 0.1 to about 0.4. For example, in certain embodiments, y is substantially equal to 0.1, 0.2, 0.3, 0.4, 0.5, 0.6, etc. X may similarly be varied between about 0.05 to about 0.5, such as about 0.1 to about 0.3. For example, in certain embodiments, xis substantially equal to 0.1, 0.2, 0.3, 0.4, 0.5, etc. The lithium, ruthenium, cobalt, and oxygen containing material described herein, may be described as LRCO material and films formed from the LRCO material may be described as LRCO thin films. The atomic ratio of each of the elements within the LRCO material may vary as described herein, but include each of lithium, ruthenium, cobalt, and oxygen, in some embodiments.

In some embodiments, other materials other than the LRCO material are utilized, such that the cathode is formed from an anion redox active material. The anion redox active material includes the LRCO material as well as other materials as described herein. The anion redox active material may be an anion redox active over-lithiated transition metal oxide. The anion redox active material is a solid solution of one or a combination of lithiated ruthenium oxide (Li₂RuO₃) and lithiated iridium oxide (Li₂IrO₃) along with at least one lithium metal oxide. The lithium metal oxides include lithium oxides of iron (Fe), cobalt (Co), nickel (Ni), manganese (Mn), tin (Sn), titanium (Ti), palladium (Pd), silver (Ag), zinc (Zn), gallium (Ga), indium (in), and vanadium (V). In some embodiments the lithium metal oxides include one or a combination of iron (Fe), cobalt (Co), nickel (Ni), manganese (Mn), tin (Sn), titanium (Ti), and vanadium (V). The lithium metal oxides include one or a combination of lithium iron oxide, lithium cobalt oxide, lithium nickel oxide (LNO), lithium manganese oxide (LMO), lithium tin oxide, lithium titanium oxide (LTO), and lithium vanadium oxide. The lithium metal oxides therefore includes one or a combination of LiFeO₂, LiCoO₂, LiNiO₂, LiMnO₂, LiMn₂O₄, Li₂MnO₃, LiSnO, Li₂TiO₃, and LiV₃O₈.

In some embodiments where tin is substituted for cobalt, the solid solution of LiRu₂O₃ and LiCoO₂ is replaced by a solid solution including LiRu₂O₃ and LiSnO₂. In some embodiments where iridium is substituted for cobalt, the solid solution of LiRu₂O₃ and LiCoO₂ is replaced by a solid solution including LiRu₂O₃ and Li₂IrO₃. Similarly, alternative transition metals such as manganese (Mn), may be substituted with ruthenium (Ru) within the composition. In some embodiments where manganese is substituted with ruthenium, the solid solution of LiRu₂O₃ and LiCoO₂ is replaced by a solid solution including LiMn₂O₄ and LiCoO₂ or a solid solution including LiMnO₂ and LiCoO₂. In some embodiments, one or a combination of LiRu₂O₃ and LiMn₂O₄ may be combined with any one or a combination of LiCoO₂, LiSnO₂, and Li₂IrO₃. Other combinations of over-lithiated transition metal oxides are contemplated, but not explicitly disclosed herein. Substitution of compounds within the composition is enabled at least in part by the ability of oxygen atoms within the compounds to participate in redox reactions. At least Li₂RuO₃ and Li₂IrO₃ have improved electrical conductivity compared to other lithium metal oxides. Therefore, at least one of the Li₂RuO₃ and Li₂IrO₃ compounds are utilized. Improved electrical conductivity improves thin film battery performance. At least one of the anion redox active materials is the LRCO material described herein.

In some embodiments, the cathode material is deposited on a rigid substrate. In further embodiments, the cathode material is deposited on a flexible substrate. As used herein, “flexible” is defined as being capable of at least one of bending, stretching, and/or compressing without causing cracks, breaks, fine cracks and the like. In some embodiments, a flexible substrate can be made of or can include a metal. Non-limiting examples of flexible metal substrates are platinum foil and aluminum foil. In some embodiments, a flexible substrate is a thermoplastic substrate. Thermoplastic substrates include amorphous thermoplastics, semi-crystalline thermoplastics, crystalline thermoplastics, and elastomeric and include, without limitation, polyimides, poly(aryletherketone) (PAEK), poly(butylene terephthalate) (PBT), poly(butyrate), poly(ether ether ketone) (PEEK), poly(etherimide) (PEI), poly(2-hydroxyethyl methacrylate) (pH EMA), poly(isocyanurate) (PIR), poly(methyl methacrylate) (PMMA), poly(oxymethylene) (POM); poly(phenylsulfone) (PPSF), poly(styrene) (PS), poly(trimethylene terephthalate) (PTT), poly(urea) (PU); poly(amide)-based thermoplastics like aliphatic poly(amides), poly(phthalamides) (PPA), and aramides (aromatic poly(amides)); poly(carbonate)-based thermoplastics; poly(ester)-based thermoplastics like poly(ethylene) naphthalate (PEN), and poly(ethylene terephthalate) (PET); poly(olefin)-based thermoplastics like poly(ethylene) (PE), poly(propylene) (PP), poly(propylene carbonate) (PPC), poly(methylpentene) (PMP), and poly(butene-1) (PB-1); poly(stannane)-based thermoplastics; poly(sulfone)-based thermoplastics; poly(vinyl)-based thermoplastics like poly(vinyl chloride) (PVC), poly(vinylidene fluoride) (PVDF), poly(vinyl fluoride) (PVF), poly(vinyl nitrate) (PVN), and poly-(4-vinylphenol) (PVP); and cellulose-based thermoplastic like cellulose ester-based thermoplastics and cellulose ether-based thermoplastics.

In some embodiments, the electrolyte comprises lithium phosphorus oxynitride (LiPON). In further embodiments, the electrolyte can comprise LiAlSiO₄, lithium lanthanum titanate (LLTO), lithium phosphorous sulfuric oxynitrides (LiPSON), lithium boron oxynitride (LiBON), LiPON, and combinations thereof.

As described herein, an LRCO cathode is deposited in a thin film format. The thin film format and LRCO cathode described herein are theorized to provide almost double the charge storage capacity relative to previous cathode materials. As described herein, the LRCO thin film batteries were prepared by RF magnetron sputtering, and then integrated into thin film batteries. The LRCO thin films may be formed using an LRCO containing sputtering target. The LRCO containing sputtering target may be sputtered onto a substrate using an RF magnetron sputtering technique, such that an RF power is applied to a magnetron assembly of a process chamber and the LRCO material is sputtered from the sputtering target onto a substrate disposed within the process chamber.

Experimental methods utilized to form exemplary LRCO cathodes and thin film batteries are further described herein. The resultant LRCO cathodes and thin film batteries were then tested as described herein.

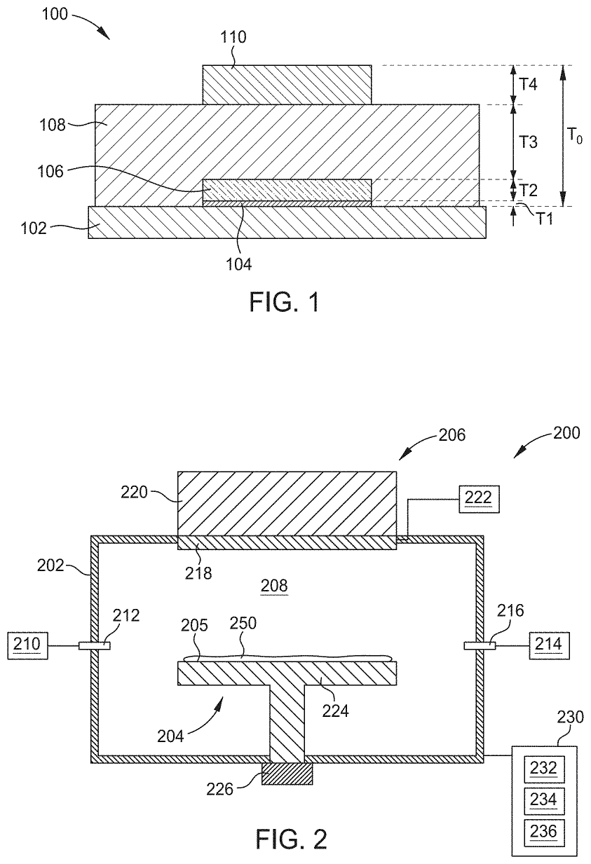

FIG. 1 is a schematic cross-sectional view of a thin film battery 100, according to embodiments described herein. The thin film battery 100 includes a substrate 102, a current collector 104, a cathode 106, an electrolyte 108, and an anode 110. The substrate 102 may be used to support the current collector 104, the cathode 106, the electrolyte 108, and the anode 110. In some embodiments, the cathode 106 is disposed between the current collector 104 and the electrolyte 108. In some embodiments, the electrolyte 108 is disposed between the cathode 106 and the anode 110. As described herein, the cathode 106 is an LRCO electrode and contains each of lithium, ruthenium, cobalt, and oxygen.

The substrate 102 may be an inorganic material, an organic material, or a combination thereof. Inorganic materials include silicon, aluminum oxide (Al₂O₃), quartz, and some polymers. In other embodiments, the methods described herein enable the use of an organic material for the substrate 102, such as one or more polymers. As described herein, methods used to form the cathode 106 enable the use of lower cost, flexible substrates, such as polymer substrates. As described herein, the substrate 102 is a support substrate and is generally used to support the other elements of the thin film battery 100. The other elements of the thin film battery 100 are formed on top of the substrate and the substrate may be later diced or cut to form a plurality of thin-film batteries 100.

The current collector 104 is formed on top of the substrate 102. The current collector 104 may be a thin-film current collector deposited onto the substrate 102. The current collector 104 may be formed of an electronically conductive material. In some embodiments, the current collector 104 is formed of gold, silver, platinum, aluminum, carbon based current collectors, or a combination thereof. Other electronically conductive materials are envisioned, but not listed herein for brevity. In some embodiments, the current collector 104 is a platinum metal current collector. The current collector 104 may have a collector thickness T1 of greater than about 50 nm, such as greater than about 200 nm, such as about 200 nm to about 1000 nm, such as about 200 nm to about 500 nm. In some embodiments, the collector thickness T1 is about 50 nm to about 200 nm.

The cathode 106 is formed on top of the current collector 104, such that the current collector 104 provides a low electronic resistance connection to the cathode 106. The cathode 106 as described herein is an LRCO electrode. The LRCO electrode contains each of lithium, ruthenium, cobalt, and oxygen. The general composition of the LRCO electrode layer may follow the atomic ratio provided by the formula (1−x)Li₂RuO₃+xLiCoO₂+yLi₂O). Y is varied between about 0.05 and 0.6, such as about 0.1 to about 0.4, such as about 0.2 to about 0.3. X is varied between 0.05 and 0.5, such as about 0.1 to about 0.3, such as about 0.2 to about 0.3. As described herein, x and y may be equal to 0.1, 0.2, or 0.3. As described above, the LRCO composition may be formed using a combination of Li2RuO3 and LiCoO2. The ratio of Li₂RuO₃ to LiCoO₂ may be changed to vary the cobalt concentration within the composition. In embodiments wherein x is greater than about 0.3, the discharge capacity has generally been shown to be lower. In embodiments where x and y are estimated to be the same, the formula is Li₂₊ₓRu₁₋ₓCoₓO₃. The atomic ratio provided by the formula Li₂₊ₓRu₁₋ₓCoₓO₃ is an approximation and the composition ratio may be altered slightly to fall within the atomic ratios described herein.

In some embodiments, the cathode is formed on top of the current collection 104, but the current collector 104 is a free standing current collector. The free standing current collector is not disposed on a substrate, such as the substrate 102. In this embodiment, the current collector 104 may be a thin foil, such as an electrically conductive foil. In some embodiments, the cathode is formed on top of the current collector 104 and the current collector 104 is later removed from the substrate 102, such that the substrate 102 is removable.

As described herein, the atomic ratio of lithium to ruthenium within the cathode 106 may be about 6:1 to about 2:1, such as about 5:1 to about 2.2:1, such as about 4:1 to about 2.5:1. In some embodiments, the atomic ratio of lithium to cobalt is controlled to be about 23:1 to about 4:1, such as about 21:1 to about 5:1, such as about 15:1 to about 6:1, such as about 12:1 to about 6:1. The ratio of cobalt has been shown to directly impact the electrochemical performance of the thin film battery 100, such that cobalt concentrations of about x=0.1 to about x=0.3 have improved electrochemical performance. In some embodiments, the cobalt concentrations of about x=0.2 to about x=0.3 have improved electrochemical performance over cobalt concentrations of x=0.1. The atomic ratio of ruthenium to cobalt may be about 10:1 to about 1:1, such as about 8:1 to about 2:1, such as about 7:1 to about 2:1.

The cathode 106 further has a cathode thickness T2. The cathode thickness T2 is large enough to cover the current collector 104 while forming a thin film cathode for the thin film battery 100. As described herein, the cathode 106 can have a cathode thickness T2 of greater than about 50 nm, such as about 50 nm to about 40,000 nm, such as about 50 nm to about 4,000 nm, such as about 50 nm to about 750 nm, such as about 100 nm to about 500 nm, such as about 100 nm to about 350 nm, such as about 250 nm or about 300 nm. The cathode composition described herein enables a thin film cathode to be formed with relative uniformity across the cathode. As described herein, the cathodes have greater uniformity when deposited as an amorphous layer using physical vapor deposition (PVD) and before being annealed.

In embodiments described herein, the cathode 106 within the thin-film battery 100 may be either an annealed or an unannealed film. When the cathode 106 is deposited using a PVD operation, no binder is utilized and the cathode 106 may be fully amorphous and non-crystalline. In embodiments herein, the crystal grain size is below 300 nm to reduce the likelihood of shorts within the thin film battery 100. The reduced crystal grain size further provides higher Coulombic efficiency and reduced capacity fading. In some embodiments, the crystal grain size is less than 250 nm, such as less than 200 nm, such as less than 150 nm, such as less than 100 nm. With increased crystal grain size, the electrolyte 108 thickness would be increased to reduce the likelihood of shorts and therefore limiting the columbic efficiency, cost, and size of the thin-film battery 100.

The cathode 106 has a surface roughness (Ra) of less than about 1000 nm, such as less than about 700 nm, such as less than about 500 nm, such as less than about 300 nm. The reduced surface roughness enables improved formation of the electrolyte thereon and reduces the potential for shorting of the thin film battery 100. The surface roughness is directly correlated to the crystal grain size and is reduced with the reduction in crystal grain size.

The electrolyte 108 is formed on top of the cathode 106 and the substrate 102, such that the electrolyte 108 entirely covers the surface of the cathode 106. The electrolyte 108 is a solid-state electrolyte and may be deposited on the substrate 102 in a similar manner to the cathode 106, such as by a solution casting or a CVD or PVD process. As described herein, the electrolyte 108 may be a solid lithium-ion conductor. The solid lithium-ion conductor is utilized to conduct lithium ions between the cathode 106 and the anode 110. The electrolyte 108 may be described herein is a Lithium phosphorus oxynitride (LiPON) material. The LiPON material has a general formula of LiₓPO_{y}N_{z}, where x−2y+3z−5 for various combinations of y and z. One exemplary atomic ratio is Li_{3.3}PO_{3.9}N_{0.17}. Additional examples of potential electrolytes may be found in any one of BATES, J. B. (1992). Electrical properties of amorphous lithium electrolyte thin films. Solid State Ionics, 53-56, 647-654. https://doi.org/10.1016/0167-2738(92)90442-r, Bates, J. B., Dudney, N. J., Gruzalski, G. R., Zuhr, R. A., Choudhury, A., Luck, C. F., & Robertson, J. D. (1993). Fabrication and characterization of amorphous lithium electrolyte thin films and rechargeable thin-film batteries. Journal of Power Sources, 43(1-3), 103-110. https://doi.org/10.1016/0378-7753(93)80106-y, as well as Yu, X., Bates, J. B., Jellison, G. E., Hart, F. X. (1997). A stable thin-film lithium electrolyte: Lithium phosphorus oxynitride. Journal of The Electrochemical Society, 144(2), 524-532. https://doi.org/10.1149/1.1837443.

An electrolyte thickness T3 is a thickness of the electrolyte 108 formed on top of the cathode 106. The electrolyte thickness T3 may be the distance separating the cathode 106 and the anode 110. The electrolyte thickness may be about 0.05 μm to about 3 μm, such as about 0.5 μm to about 2 μm, such as about 1 μm to about 1.5 μm.

The anode 110 is disposed on top of the electrolyte 108. The anode 110 may be deposited using a slurry coating or a PVD process. Other deposition processes may also be utilized, such as a chemical vapor deposition (CVD) or atomic layer deposition (ALD). The anode 110 can be prefabricated, for example, a lithium metal foil. The anode 110 may be a graphite, a lithium metal, silicon alloys, titanium oxides, or other metallic materials. Other metallic materials may include germanium, indium, aluminum, tin, magnesium, zinc, silver, or gold. In some embodiments, the anode 110 includes Li₄Ti₅O₁₂, TiO₂, or SnO₂. In embodiments described herein, the anode 110 is a lithium metal anode. In one example, the anode 110 is a lithium metal thin film. The anode 110 has an anode thickness T4. The anode thickness T4 can be about 0.05 μm to about 10 μm, such as about 1 μm to about 10 μm, such as about 1 μm to about 5 μm, such as about 1 μm to about 3 μm, such as about 2 μm.

In some embodiments, the anode 110 is replaced by a metallic thin film. The metallic thin film may be formed of a metal or a metal alloy. In some embodiments, the metallic thin film is one or a combination of nickel or copper. The metallic thin film is similarly deposited onto the electrolyte 108. When using the metallic thin film, lithium metal plates onto the metallic film during charging of the thin film battery 100 and is stripped from the metallic thin film during discharge of the thin film battery 100. In some embodiments, the electrolyte 108 comprises a lithium ion conductor and the lithium metal plates and is stripped from the metallic thin film during charging and discharging. In this embodiment, the metallic thin film serves as a current collector and the thin film battery 100 is an anode-free thin film battery.

The total thickness To of the thin film battery 100, excluding the substrate 102, is less than about 150 μm, such as less than about 100 μm, such as less than about 50 μm, such as less than about 30 μm, such as less than about 25 μm, such as less than 20 μm, such as less than 10 μm. The small total thickness T₀ of the thin film battery 100 enables the thin film battery 100 to be utilized in a large amount of applications, such as in medical devices, micro-computers, tiny robots, etc. Additional layers and materials may also be used within the thin film battery 100.

In some embodiments, the substrate 102 may be omitted and the current collector 104 is utilized as a base of the thin film battery 100. In these embodiments, the current collector 104 may form the entire bottom surface of the thin film battery 100.

In yet other embodiments, the structure of the thin film battery 100 may be flipped, such that the anode 110 is disposed on a current collector on the substrate 102, an electrolyte 108 is disposed on top of the anode 110 and the substrate 102, and the cathode 106 is formed on top of the electrolyte 108. In this embodiments, the anode 110 and the cathode 106 of FIG. 1 are switched and a cathode current collector may be disposed on top of the cathode 106.

In some embodiments, multiple thin film batteries 100 are stacked on top of each other, such that each individual thin film battery 100 forms a cell and two or more cells are stacked on top of each other. In these embodiments, a second current collector and/or a second cathode is disposed on top of the anode 100, a metallic thin film, and/or the electrolyte 108. A second electrolyte is formed on top of the second cathode/the second current collector, and a second anode is formed on top of the second electrolyte. A third and/or a fourth battery cell may be disposed on top of the second cell. Stacking of the thin film batteries 100 is enabled by the lack of an annealing operation, such that the thin film battery 100 is kept below about 700° C., such as below about 500° C., such as below about 300° C. Maintaining a low temperature formation process enables stacking as the electrolyte 108 material is not damaged or destroyed as it would be at elevated temperatures, such as temperatures greater than about 300° C.

In some embodiments, the thin film battery 100 includes a cathode 106 comprising an anion redox active material. The anion redox active material is a solid solution of one or a combination of lithiated ruthenium oxide (Li₂RuO₃) and lithiated iridium oxide (Li₂IrO₃) along with at least one lithium metal oxide. The lithium metal oxides include lithium oxides of iron (Fe), cobalt (Co), nickel (Ni), manganese (Mn), tin (Sn), titanium (Ti), palladium (Pd), silver (Ag), zinc (Zn), gallium (Ga), indium (In), aluminum (Al), and vanadium (V). In some embodiments the lithium metal oxides include one or a combination of iron (Fe), cobalt (Co), nickel (Ni), manganese (Mn), tin (Sn), titanium (Ti), aluminum (Al), and vanadium (V). The lithium metal oxides include one or a combination of lithium iron oxide, lithium cobalt oxide, lithium nickel oxide (LNO), lithium manganese oxide (LMO), lithium tin oxide, lithium titanium oxide (LTO), lithiated nickel-manganese oxide (NMC), lithiated nickel-cobalt-aluminum oxide (NCA), and lithium vanadium oxide. The lithium metal oxides therefore includes one or a combination of LiFeO₂, LiCoO₂, LiNiO₂, LiMnO₂, LiMn₂O₄, Li₂MnO₃, LiSnO, Li₂TiO₃, LiNi_{1-x-y}MnₓCo_{y}O₂, LiNi_{0.8}Co_{0.15}Al_{0.05}O₂, and LiV₃O₈.

The thin film battery 100 further includes an anode 110 disposed adjacent to the cathode 106 and an electrolyte 108 disposed between the cathode 106 and the anode 110. The anode 110, the electrolyte 108, the current collector, and the substrate 102 are similar to those previously described. The methods of forming the thin film battery 100 may be the same for the different combinations of the two or more metals. In one embodiment, the method of forming the thin film battery 100 includes depositing a cathode 106 onto a support substrate 102 within a process volume of a processing chamber, depositing an electrolyte 108 over the cathode 106, and depositing an anode 110 over the electrolyte 108. The cathode 106 includes lithium, oxygen, and at least two of ruthenium, cobalt, tin, iridium, and manganese.

FIG. 2 is a schematic cross-sectional view of a processing chamber 200 for depositing one or more films, according to embodiments described herein. The processing chamber includes a chamber body 202, a substrate support assembly 204 disposed within the chamber body 202, a sputtering assembly 206 disposed on top of the chamber body 202, a gas source 210, an exhaust pump 214, and a controller 230. The processing chamber 200 described herein is used to form one or more thin films on a substrate 250. The thin films may be similar to the films illustrated in FIG. 1 and the thin film battery 100.

The chamber body 202 includes a process volume 208 disposed therein. The process volume 208 may be isolated from the atmosphere around the chamber body 202, such that the process volume 208 is vacuum isolated. The chamber body 202 may include a plurality of openings disposed therethrough to enable other components to be inserted into the chamber body 202 and the process volume 208.

The substrate support assembly 204 is disposed within the process volume 208 and includes a support pedestal 224 and an actuator 226 coupled to the support pedestal 224. The support pedestal 224 is configured to support the substrate 250 and includes a substrate support surface 205. The support pedestal 224 may be configured with one or more heaters, one or more cooling channels, and one or more backside gas lines disposed therein (not shown). The actuator 226 is configured to move the support pedestal 224, such that the actuator 226 may move the support pedestal 224 in a vertical direction or it may rotate the substrate about an axis of the support pedestal 224. In embodiments described herein, the support pedestal 224 is configured to be raised and lowered to be moved proximate to a sputtering target 218 during substrate processing.

The sputtering assembly 206 is disposed above the substrate support assembly 204. The sputtering assembly 206 is configured to sputter one or more materials onto the substrate 150. The sputtering assembly 206 includes a sputtering target 218, a magnetron assembly 220, and a power source 222. The power source 222 is configured to supply power to the magnetron assembly 220. The power source 222 may further bias the sputtering assembly 206 by biasing the sputtering target 218. The power source 222 may be an AC or RF power source. The magnetron assembly 220 includes a plurality of magnets disposed therein and configured to move within a volume of the magnetron assembly 220. At least one side of the sputtering target 218 is exposed to the process volume 208, such that a side of the sputtering target 218 facing the substrate 250 is disposed within the process volume 208. In other embodiments, the location of the sputtering assembly 206 and the substrate support assembly 204 is reversed such that the sputtering assembly 206 is disposed below the substrate support assembly 204 and the substrate 102.

A gas source 210 is in fluid communication with the process volume 208 and is configured to supply one or more process gases into the process volume 208 through one or more openings 212 disposed within the chamber body 202. The gas source 210 may be configured to flow a single gas, a gas mixture, or multiple gases into the process volume 208. In some embodiments, the gas source 210 comprises multiple gas sources. In embodiments described herein, the gas source 210 is configured to supply one or more inert gases, such as helium, neon, or argon. The gas source 210 may also be configured to supply a process gas such as nitrogen or oxygen into the process volume 208.

An exhaust pump 214 is also in fluid communication with the process volume 208 and is configured to remove one or more process gases from the process volume 208. The exhaust pump 214 removes the process gases through one or more exhaust openings 216 disposed through the chamber body 202. The exhaust pump 214 may apply a vacuum to the process volume 208. In embodiments described herein, the gas source 210 and the exhaust pump 214 may purge the process volume 208 between process operations or when a substrate, such as the substrate 250 is moved into or out of the process volume 208.

The controller 230 is configured to control the processing of the substrate 250 within the processing chamber 200. The controller 230 as described herein, may be configured to control the actuator 226, the sputtering assembly 206, the gas source 210, and the exhaust pump 214. The controller 230 may be one or a plurality of individual controllers. The controller 230 is a general use computer that is used to control one or more components found in the processing chamber 200. The system controller 230 is generally designed to facilitate the control and automation of one or more of the processing sequences disclosed herein and typically includes a central processing unit (CPU) 232, memory 234, and support circuits (or I/O) 236. Software instructions and data can be coded and stored within the memory 234 (e.g., non- transitory computer readable medium) for instructing the CPU 232. A program (or computer instructions) readable by the processing unit within the system controller determines which tasks are performable in the processing chamber 200. For example, a non-transitory computer readable medium includes a program which when executed by the CPU 232 are configured to perform one or more of the methods described herein. Preferably, the program includes code to perform tasks relating to monitoring, execution and control of the movement, support, and/or positioning of a substrate along with the various process recipe tasks and various processing module process recipe steps being performed.

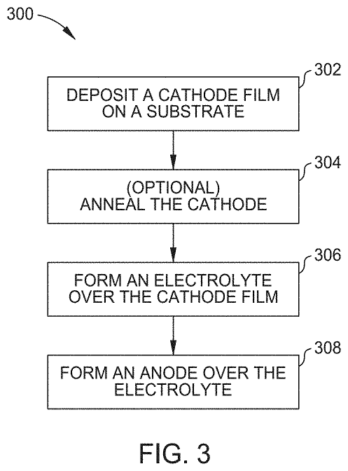

FIG. 3 illustrates a method 300 of forming the thin film battery 100 of FIG. 1. The method 300 enables the formation of thin film batteries with reduced thickness and increased capacity. The method 300 may be performed in one or more process chambers similar to the processing chamber 200 of FIG. 2. The method 300 includes an operation 302 of depositing a cathode film, such as the cathode 106, on a substrate, such as the substrate 102. In embodiments described herein, a current collector, such as the current collector 104, is already disposed on the substrate. The current collector described herein may be formed from any one of gold, silver, platinum, carbon nanotubes, other conductive materials, or a combination thereof.

The formation of the cathode film may be performed using a suitable deposition technique. As described herein, the cathode film may be deposited either using a slurry coating or using a CVD or PVD operation. Forming the cathode film on the substrate using the PVD operation has been shown to allow more uniform deposition with smaller crystal grain sizes. When depositing the cathode film using the PVD operation, the cathode film may be an amorphous film. The PVD operation includes sputtering an LRCO material from a sputtering target, such as the sputtering target 218, onto the substrate. The sputtering target is formed from an LRCO material, such as an LRCO-1, LRCO-2, or LRCO-3 material as described herein. The LRCO material forming the sputtering target includes each of lithium, ruthenium, cobalt, and oxygen.

During deposition of the LRCO material, the processing chamber is evacuated to a base pressure of about 1·10⁻⁸ Torr to about 1·10⁻⁵ Torr, such as about 1·10⁻⁷ Torr to about 1·10⁻⁶ Torr, such as about 5.10⁻⁷ Torr. After evacuating to the base pressure, the processing chamber is brought to a working pressure. The working pressure is about 1 mTorr to about 5 Torr, such as 10 mTorr to about 1 Torr, such as about 15 mTorr. The working pressure is the pressure at which the cathode film is formed using the PVD process.

A power is applied to a magnetron assembly, such as the magnetron assembly 206 of FIG. 2. The power density applied to the sputtering assembly is about 1 W/cm² to about 8 W/cm², such as about 1.2 W/cm² to about 7.5 W/cm², such as about 2 W/cm² to about 6 W/cm², such as 2.5 W/cm² to about 5 W/cm², such as about 3 W/cm² to about 4 W/cm².

The substrate is disposed at a sputtering distance from a surface of a sputtering target, such as the sputtering target 218. The sputtering distance is the distance between the surface of the sputtering target which faces the substrate and a top surface of the substrate. The sputtering distance during the PVD process is about 3 cm to about 25 cm, such as about 5 cm to about 20 cm, such as about 5 cm to about 15 cm, such as about 5 cm to 10 cm. In exemplary embodiments described herein, the sputtering distance is one of 5 cm or 10 cm.

During the PVD process one or more process gases may be flowed into the process volume. The process gases include one or more inert gases and one or more process gases. The one or more inert gases may be one of helium, neon, or argon. As described herein, the inert gas is argon. The inert gas is flowed at a flow rate of about 1 sccm to about 20 sccm, such as about 2 sccm to about 10 sccm, such as about 3 sccm to about 5 sccm. A second gas, such as a process gas is also supplied to the process volume during PVD processing. The second gas may be one of nitrogen (N₂), oxygen (O₂), or a combination thereof. In exemplary embodiments described herein, the second gas is oxygen and is flowed into the process volume at a flow rate of about 0.5 sccm to about 5 sccm, such as about 1 sccm to about 3 sccm, such as about 1 sccm.

While the cathode layer is being deposited onto the substrate, the temperature within the process volume is less than about 100° C. The reduced temperature enables the use of additional substrate materials other than aluminum oxide, silicon, or quartz substrates. In some embodiments, a polymer containing substrate may be utilized. The polymer containing substrate may be an organic or an inorganic substrate.

The above process conditions of the PVD deposition of the LRCO cathode are exemplary. The process conditions may be adjusted to compensate for varying chamber configurations, deposition rates, and substrate size.

After depositing the cathode on the substrate, the cathode may optionally be annealed during an operation 304. The optional anneal of the cathode is performed at a duration of at least about 1 hour, such as about 1 hour to about 20 hours, such as about 1 hour to about 10 hours, such as about 1 hour to about 6 hours, such as about 1 hour. The annealing temperature is about 100° C. to about 800° C., such as about 100° C. to about 700° C., such as about 400° C. to about 650° C. The length and temperature of the cathode during operation 304 is directly correlated to the crystal grain size produced within the cathode. In embodiments described herein, the crystal grain size after the optional anneal is less than 250 nm, such as less than 200 nm, such as less than 150 nm, such as less than 100 nm. In embodiments wherein there is no anneal, the cathode remains amorphous.

In embodiments both with and without the optional anneal operation 304, an electrolyte is formed over the cathode layer during an operation 306. The formation of the electrolyte may be performed using similar deposition conditions as the deposition of the cathode layer. In some embodiments, the electrolyte is also formed using a PVD process. In other embodiments, the electrolyte is deposited using a CVD or ALD process. Other processes may also be utilized to form the electrolyte. The electrolyte is a solid lithium-ion conductor. In some embodiments, the electrolyte is formed from a LiPON material. The electrolyte may be sputtered onto the substrate using a LiPON sputtering target, such that the cathode is covered by the electrolyte.

After the cathode layer has been covered by the electrolyte, an anode is formed over the electrolyte during an operation 308. The anode may be similar to the anode 110 of FIG. 1. The anode is formed using a similar method to those used to deposit the cathode and the electrolyte. The anode may be deposited using one of a PVD process, a CVD process, an ALD process, etc. The anode can be prefabricated, for example, a lithium metal foil. The anode formed of one or a combination of graphite, lithium metal, or another metallic material. In embodiments described herein, the anode is a lithium metal anode. The anode is deposited in a different process chamber than the cathode or the electrolyte, such that each of the anode, the electrolyte, and the cathode are formed in separate process chambers.

In some embodiments, the substrate 102 is omitted or replaced. In embodiments in which the substrate 102 is omitted, the current collector 104 has a greater thickness and the cathode 104, the electrolyte 108, and the anode 110 are formed on the current collector without a substrate 102 disposed beneath the current collector 104.

In some embodiments, the structure of the thin film battery 100 is flipped, such that an anode current collector is disposed on top of the substrate 100. The anode 110 may then be disposed on top of an anode current collector before forming the electrolyte 108 over the anode 110. Once the electrolyte 108 is formed, the cathode 106 may be subsequently formed over the electrolyte 108. In this embodiment, the current collector 104 may be disposed on top of the cathode 106 and distal from the substrate 100. In this embodiment, the operation 308 is performed before either of operations 302, 304, or 306. Operation 308 is modified such that the anode is deposited on the substrate. After depositing the anode, the electrolyte is deposited during the operation 306. The cathode may then subsequently be deposited on the electrolyte and annealed during operations 302 and 304.

### EXPERIMENTATION

The following non-limiting examples are provided to further illustrate embodiments described herein. However, the examples are not intended to be all inclusive and are not intended to limit the scope of the embodiments described herein.

### EXAMPLE 1

The materials and methods described above were tested experimentally as described below. Initially, a LRCO powder was synthesized. The LRCO material was prepared using solid state methods. Li₂CO₃ (Alfa Aesar, 99.9% purity, 10 wt. % excess), RuO₂ (Alfa Aesar, 99.9% purity), and CoCO₃ (Alfa Aesar, 99.9% purity) precursors were weighed according to the desired stoichiometry, mixed with anhydrous acetone (Fisher Chemical), and ground in a planetary ball mill (DECO, PBM-V-0.4L). Excess Li₂CO₃ was included to compensate for possible Li loss during high temperature annealing and/or during the sputtering process in later steps. The ground/mixed powders were heated at 2° C./min in a muffle furnace (air atmosphere) to a temperature of 900-1100° C., then soaked for 12 h at the final temperature before cooling. The effect of final annealing temperature on structure and electrochemical properties was investigated.

From the LRCO powder, a LRCO target is formed. The LRCO powder, as described above, has a general chemical composition of Li_{2.2}Ru_{0.8}Co_{0.2}O₃. A two-inch sputtering target for thin film deposition was prepared by high temperature sintering of the Li_{2.2}Ru_{0.8}Co_{0.2}O₃ powder. Agglomerates in the LRCO powder were first disrupted manually using a mortar and pestle. The fine powders were then mixed with a 5 wt % solution of polyethylene oxide in N,N-dimethylformamide (DMF) binder solution, and the mixture was then heated to 70° C. to remove the DMF solvent. The LRCO and a poly(ethylene oxide) (PEO) binder mixture was cold-pressed in a two-inch diameter die at 11 metric tons for 5 minutes. The pellet was then placed in a clean alumina dish and sintered in a room-air muffle furnace. The following heating profile was used to sinter the target. The temperature was increased by 5° C./minute to 300° C. The temperature was then subsequently increased by 1° C/minute to 550° C. and dwelled at 550° C. for 0.5 hours. Burn-out of the binder is theorized to occur while at 550° C. The temperature was then subsequently increased by 20° C/minute to 900° C. and dwelled at 900° C. for about 5 hours. After dwelling at 900° C., the furnace was cooled by 2° C./minute. After the sintered target fully cooled, the target was attached to a copper backing plate (OHFC) using silver-filled, vacuum grade epoxy (Dynaloy, KL-325K). The target was cured at 70° C. under vacuum before installation in the sputtering chamber.

Once the target was installed in the chamber, a plurality of thin films were deposited on substrate within the sputtering chamber. LRCO thin films were fabricated using RF magnetron sputtering in a vacuum deposition chamber. Typical, unoptimized process parameters for the RF magnetron sputtering included a base pressure of 5.10⁻Torr, a working pressure of 15 mTorr, a power of 70 W, a substrate to target distance of 5 to 10 cm, an argon gas flow rate of 3 sccm into the deposition chamber, and an oxygen (O₂) gas flow rate of 1 sccm into the deposition chamber. Optical grade fused quartz slides (AdValue Technology, FQ-S-001, 1″ (length)×1″ (width)×0.04″ (thickness)) were used as substrates for all thin films deposited by the target. LRCO thin films on quartz slides are typically 300 nm-thick, characterized by scanning electron microscopy (SEM).

Thin films (nominally 1 μm) of lithium phosphorous oxynitride (LiPON) were directly deposited on top of the cathode layer by radio frequency (RF) magnetron sputtering of a 2-inch Li₃PO₄ powder target (99.95%, Kurt J. Lesker) in ultrapure N₂ atmosphere. The custom-built sputtering chamber was pumped to about 1·10⁻⁷ Torr using a combination of a mechanical and diffusion pump. Key deposition parameters were a forward power of 80 W, a nitrogen gas flow rate of 5 sccm, an operating nitrogen pressure of 20 mTorr, and a target-substrate distance of 5 cm. Approximately 2-μm-thick Li metal was thermally evaporated as the anode material in a vacuum chamber with a base pressure of about 1·10⁻⁶ Torr. A quartz crystal monitor (QCM) was used to in-situ monitor Li deposition rate.

For the cathode annealing process, 300nm-thick films of as-deposited LRCO (chemical composition of Li_{2.2}Ru_{0.8}Co_{0.2}O₃) were prepared, then moved to tube furnace for annealing under O₂ atmosphere. As described herein, the LRCO has a molar ratio of x=0.2 when using the molecular formula Li₂₊ₓRu₁₋ₓCoₓO₃. However, the cobalt concentration within the material may be varied. When x=0.1, the LRCO is said to be LRCO-1. When x=0.2, the LRCO is said to be LRCO-2. When x=0.3, the LRCO is said to be LRCO-3. Unless otherwise specified herein, x=2 and the LRCO material has a composition similar to LRCO-2. The furnace temperature was first ramped up to set values at a ramping rate of 2° C./min, then held for the desired time, and finally allowed to naturally cool down to room temperature.

### Material Characterization

To determine the structure of LRCO powders and thin films, X-ray powder diffraction (XRD) was conducted using a Rigaku Synergy-S diffraction system with Cu Kα microfocus X-ray source. XRD powder patterns were refined via MDI Jade 9 software. Elemental compositions (Li, Ru, and Co) of LRCO were characterized using inductively coupled plasma-mass spectrometry (ICP-MS) (Perkin Elmer NexION 2000) to determine exact stoichiometry of LRCO powder. For post-mortem analysis, the cell was carefully disassembled in an Ar-filled glove box. All samples were dried under vacuum, put into a hermetically sealed plastic bottle, and then transferred to various analysis systems. Scanning electron microscopy (SEM) and energy dispersive X-ray spectroscopy (EDS) were performed on a ZEISS Crossbeam 340 FIB-SEM system using an accelerating voltage of 7.5 kV. For analysis of the samples' cross-section, sample substrates were fractured by hand.

### Electrochemical Characterization

For liquid coin cells, a slurry was prepared by adding a binder solution containing 10 wt. % polyvinylidene fluoride (PVDF) in N-methyl-2-pyrrolidone (NMP) solvent to the LRCO powder mixture containing 80 wt. % active material and 10 wt. % Super P conductive carbon. The slurry was cast on aluminum foil current collectors and dried under vacuum at 100° C. overnight before cell assembly. Metallic Li foil (1.9 mm×0.75 mm, 99.9%, Alfa Aesar) was scraped, rolled, and cut into a disc with a diameter of 1.43 cm and put on a microporous glass fiber separator of slightly larger diameter which acted as a spacer to define the electrode separation. The electrolyte used was 100 μl of 1.0 M LiPF6 in 1:1:1 EC:EMC:DMC (Gotion). The coin cells were cycled from 2.0 V to 4.5 V using a battery cycler (BT-2043, Arbin Instruments). The first two cycles were set at a 0.02 C rate as formation period. Cell temperature was controlled at 25° C. The electrode area was defined by the geometric area of the cathode side. Potentiostatic electrochemical impedance (PEIS) measurements were executed with a 10 mV AC amplitude at room temperature over a frequency range of 3 MHz to 0.1 Hz.

Thin-film batteries were cycled inside an Ar-filled glovebox from 2.0 V to various charge potentials using a battery cycler (BT-2043, Arbin Instruments). The electrode area was defined by the geometric area of the cathode side. Potentiostatic electrochemical impedance (PEIS) measurements were executed with a 10 mV AC amplitude at room temperature over a frequency range of 3 MHz to 0.1 Hz.

### Results

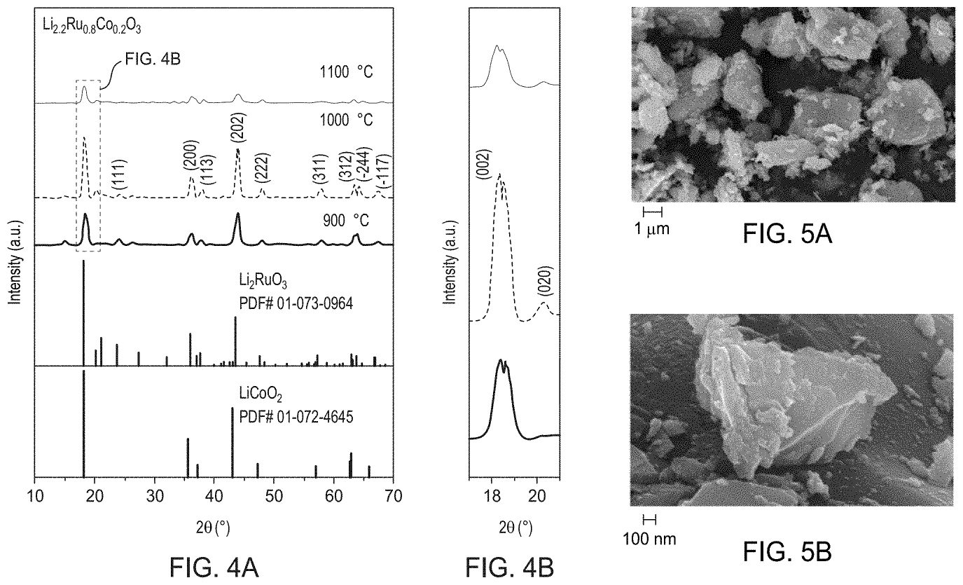

To determine the optimal annealing temperature in LRCO powder synthesis, the effect of the annealing temperatures (900° C., 1000° C. and 1100° C.) on the microstructure of Li_{2.2}Ru_{0.8}Co_{0.2}O₃ was investigated. FIGS. 4A-4B are graphs illustrating x-ray diffraction patterns of a cathode synthesized at the three different temperatures. FIG. 4B illustrates a selected area of FIG. 4A. The monoclinic Li₂RuO₃ (referred to herein as LRO) structure is indexed with PDF#01-072-4645 and the hexagonal LiCoO₂ (referred to herein as LCO) structure is indexed with PDF#01-073-0964 (diffraction data publicly available at International Center for Diffraction Data database, icdd.com). LRCO is expected to crystallize into the space group C2/c and R3m symmetries of the constituent LRO and LCO phases, respectively. All LRCO powders were indexed to the monoclinic LRO with the space group C2/c, where each LiO₆ octahedral interstitial is surrounded by six RuO₆ octahedra, thus enabling a hexagonal LiRu₆ neighbor unit in the transition metal layer. A small stacking order of the transition metal layer along monoclinic c axis of LRO could be observed at the range angle of 20-25°, especially at 900° C. and 1000° C. The cation ordering of transition metal layer can be further investigated by the intensity ratio of the characteristic peaks associated with the (002) plane and (020) plane. A higher (002)/(020) ratio indicates higher cation ordering, leading to more stacking order of the transition metal layer. As shown in FIG. 4B, the LRCO annealed at 1000° C. possesses the highest (002)/(020) ratio, indicating highest stacking order of transition metal layer and enhanced structural integrity. The (002), (010), (202), and (222) planes are divided into two peaks. One reason for (002), (010), (202), and (222) planes having two peaks is, if the diffraction peak intensity is above the sensor's linear range, the prime peak will be visibly split. Alternatively, the two peaks can be assigned to increment the degree of ordering that high temperature leads to doped metal materials more evenly dispersed in the lattice, followed by symmetry reduction because of over ordered structure.

As the annealing temperature increases, new diffraction peaks were not observed and all observed reflections were indexed to the LRO PDF card, suggesting phase purity. At low Co content (x=0.2), it is difficult to observe the diffraction peaks from LCO phases. However, the sample at higher calcination temperature (1100° C.) tends to be less crystalline due to weaker peak intensity and characteristic peaks becoming obscure.

FIGS. 5A-5B are scanning electron microscope images of an LRCO cathode material powder. As seen in the images of FIGS. 5A-5B, a disordered morphology is dominating and particles are sintered together for the sample heated at 1100° C. Compared with powders heated at 900° C. and 1100° C., the sample under 1000° C. shows sharper peaks, indicating higher crystallinity. Therefore, 1000° C. was preliminarily concluded to be the optimal annealing temperature for solid-solution reaction.

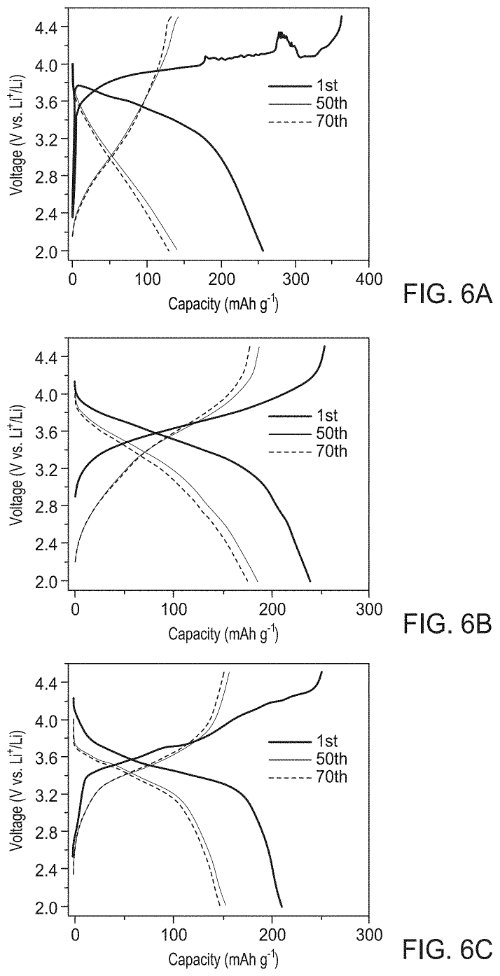

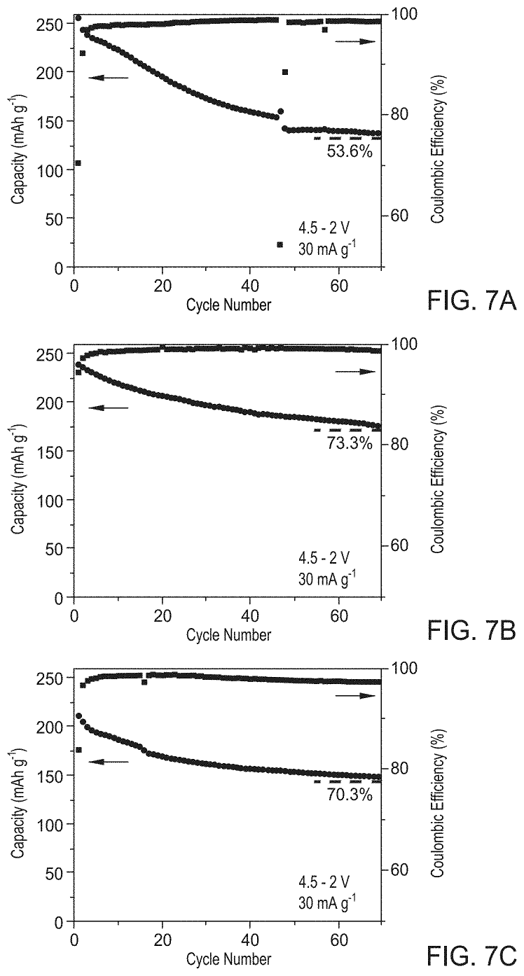

To correlate the LRCO structure obtained at the three annealing temperatures to electrochemical performance, lithium-ion battery cathodes were prepared by incorporating the LRCO powders into a typical electrode slurry and casting the slurry onto Al current collectors. The LRCO cathodes were incorporated into coin cells with Li metal anodes and standard liquid electrolyte. The battery cells were cycled galvanostatically at approximately 0.1 C (current density of 30 mA g⁻¹) from 2.0 V to 4.5 V vs. Li⁺/Li. The cathode slurries were not optimized for long-term cycling studies. Thus, the electrochemical characterization provides a comparative study to understand the effect of annealing temperature on electrochemical properties (e.g. initial charge capacities, lithiation potentials, and charge reversibility). The corresponding voltage profiles and integrated capacities are provided in FIGS. 6A-6C and FIGS. 7A-7C. FIGS. 6A-6C are graphs illustrating charge and discharge curves of assembled lithium ion cells with an LRCO cathode material after synthesizing the LRCO cathode material at various calcination temperatures. FIGS. 7A-7C are graphs illustrating cycling stability curves of the assembled lithium ion cells with the LRCO cathode material after synthesizing the LRCO cathode material at the various calcination temperatures. As illustrated FIGS. 6A-6C, when first charged to 4.5 V, delithiation from Li_{2.2}Ru_{0.8}Co_{0.2}O₃ cathodes occurs at various charging plateaus. LRCO-2 cathodes calcined at 1100° C. present two obvious charging plateaus. The first plateau is located at about 3.6 V and corresponds to oxidation of Ru⁴⁺/Ru⁵⁺. The second plateau is located at about 3.8V and corresponds to oxidation of Co³⁺/Co⁴⁺. The vertical tail above 4.2 V is due to the delithiation from the cathode side by losing oxygen and anionic redox reaction viz. peroxo-/superoxol-like species (O²⁻→O₂²⁻).

When cycling the LRCO-2 half coin cells after calcinating the cathode at a temperature of 900° C., the first discharge capacity was 255 mAh g⁻¹, the initial Coulombic efficiency was 70.5%, and the capacity retention at the 70th cycle was 53.6%. When cycling the LRCO-2 half coin cells after calcinating the cathode at a temperature of 1000° C., the first discharge capacity was 238 mAh g⁻¹, the initial Coulombic efficiency was 94.3%, and the capacity retention at the 70th cycle was 73.3%. When cycling the LRCO-2 half coin cells after calcinating the cathode at a temperature of 1100° C., the first discharge capacity was 211 mAh g⁻¹, the initial Coulombic efficiency was 83.9%, and the capacity retention at the 70th cycle was 70.3%.

At a calcination temperature of 900° C., the cycling stability was observed in FIG. 7A. The first discharge capacity was 255 mAh g⁻¹ with an initial columbic efficiency of 70.5%, indicating the highest first discharge capacity, compared to other two calcination temperature. The specific capacity gradually decreases upon cycling and dropped to 136 mAh g⁻¹ after 70 cycles, with a capacity retention of 53.6%. As shown in FIG. 7B, when the calcination temperature increased to 1000° C., the LRCO-2 cathode showed improved first discharge capacity (238 mAh g⁻¹), an initial columbic efficiency of 94.3%, and the highest capacity retention (73.3%) after 70 cycles. At 1100° C., as shown in FIG. 7C, this variant presents a first discharge capacity of 211 mAh g⁻¹, an initial columbic efficiency of 83.9%, and a capacity retention of 70.3% after 70 cycles. The sample calcined at 1000° C. also shows the highest crystallinity and cation order of transition metal (LiM₂), which improves Li ion transport, as shown in FIG. 4A. Based on a comparison of XRD powder patterns and electrochemical performance at the three calcination temperatures, 1000° C. is preliminarily considered the preferred calcination temperature of the LRCO-2 cathode.

To determine the optimal Co substitution in LRCO, a series of compounds were prepared with x=0.1, 0.2, and 0.3 in Li₂₊ₓRu₁₋ₓCoₓO₃. The compositions were varied through the ratio of CoCO₃ included in the solid-state synthesis of the LRCO powder. The compositions of the synthesized powders were confirmed using ICP-MS.

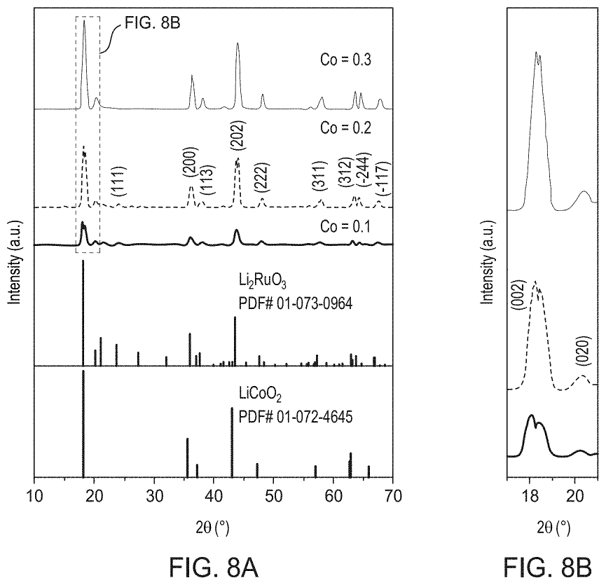

Similar microstructural and electrochemical characterization was conducted to determine the optimal Co substitutions amounts in LRCO. Microstructural characterization of Li₂₊ₓRu₁₋ₓCoO₃ series powders (x=0.1, 0.2 and 0.3) were characterized via XRD (shown in FIGS. 8A and 8B). LRCO-1, LRCO-2 and LRCO-3 crystallize into the LRO monoclinic structure. It should be noted that LRCO will not crystallize into the LCO-type rhombohedral structure until the Co content is above 0.4. FIGS. 8A-8B are graphs illustrating x-ray diffraction patterns of a cathode synthesized with varying cobalt contents.

As illustrated in FIGS. 8A and 8B, as Co substitution increases, new diffraction peaks could not be observed and all current peaks could be indexed with the LRO PDF card, suggesting phase purity. Sharper peaks are observed as the Co content increases, indicating higher crystallinity. The substitution of Ru with Co led to the crystalline structure changing and is noted through decreased superlattice peak intensities (20°-30°). When x=0.3, the peak intensities dropped to a negligible level. The presence of small superlattice peaks can be used to reflect intra-planar cation ordering of Li and Ru/Co in the transition metal layer.

As shown in FIG. 8B, samples with increased cobalt content (x=0.2 and 0.3) had a higher (002)/(020) ratio than that of samples with lower cobalt content (x=0.1). This indicates greater stacking order of transition metal layers and enhanced structural integrity. This is consistent with our expectation of electrochemical performance that Cobalt at x=0.2 and x=0.3 has similar but higher capacity retention than Cobalt at x=0.1 after 70 cycles (FIGS. 7A-7C and FIGS. 10A-10B). Only the (010) plane disappeared when Co content reached x=0.3. This is due to the decreased Ru ratio. The intensity of most other crystalline planes were enhanced when x=0.3. Therefore, compared to x=0.1, Co ratio of x=0.2 and x=0.3 are beneficial.

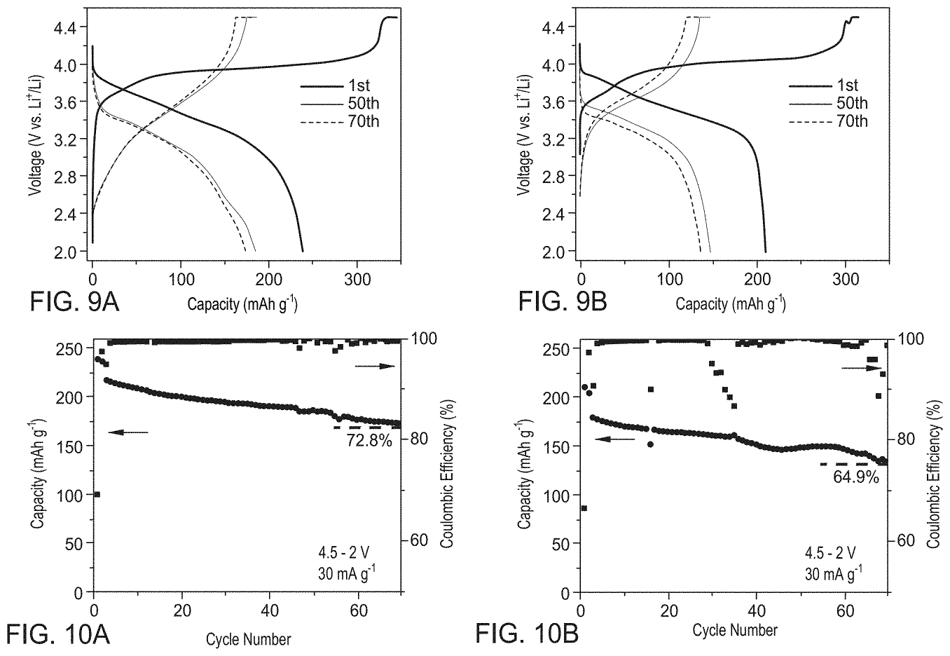

To assess the effect of cobalt substitution on electrochemical performance, LRCO-1 and LRCO-3 were incorporated into lithium-ion half cells and cycled galvanostatically using the previous cycling protocols. FIGS. 9A-9B and 10A-10B reveal that LRCO-1 and LRCO-3 deliver an initial discharge capacity of 238 mAh g⁻¹ and 210 mAh g⁻¹, respectively.

FIGS. 9A-9B illustrate charge and discharge curves of assembled lithium ion cells with an LRCO cathode material after synthesizing the LRCO cathode material with varying cobalt contents. FIG. 9A illustrates the charge/discharge curves when the LRCO cathode material has a cobalt content of x=0.1. FIG. 9B illustrates the charge/discharge curves when the LRCO cathode material has a cobalt content of x=0.3.

FIGS. 10A-10B illustrate cycling stability curves of the assembled lithium ion cells with the LRCO cathode material after synthesizing the LRCO cathode material with varying cobalt contents. FIG. 10A illustrates the cycling stability curves when the LRCO cathode material has a cobalt content of x=0.1. FIG. 10B illustrates the cycling stability curves when the LRCO cathode material has a cobalt content of x=0.3.

As seen in FIGS. 10A and 10B, as the Co substitution increased to x=0.3, capacity retention decreased from 72.8% (obtained at x=0.1) to 64.9%. This suggests that lower concentrations of cobalt provide better electrochemical performance by providing reversible anionic redox chemistry, cation ordering within the superlattice structure, and facile charge transfer process.

The synthesis of LRCO-2 (Li_{2.2}Ru_{0.8}Co_{0.2}O₃) cathode powder was conducted based on desired calcination temperature and cobalt content, followed by preparation of a sputtering target. The LRCO-2 composition was consolidated into a 2″ diameter sputtering target (LRCO sputtering target) by high temperature sintering. Thin film cathodes were prepared via RF-sputtering of the LRCO sputtering target. The resulting cathodes were dense lithium insertion compounds (e.g. lithium metal oxides) that are fabricated in a “thin” supported film format and function as the positive electrode in a solid-state electrochemical cell. These electrochemical cells include a support substrate, a thin film cathode, a solid lithium-ion conductor (i.e. a solid electrolyte), and an anode (such as lithium metal).

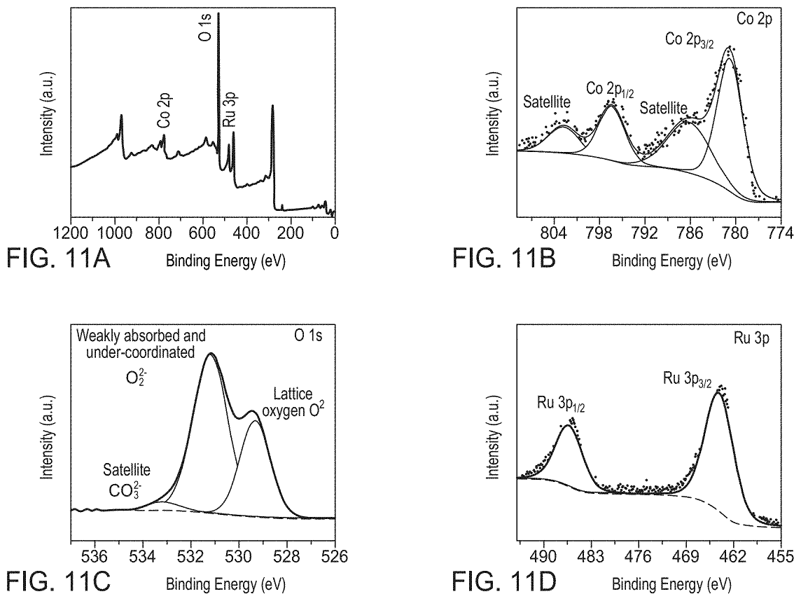

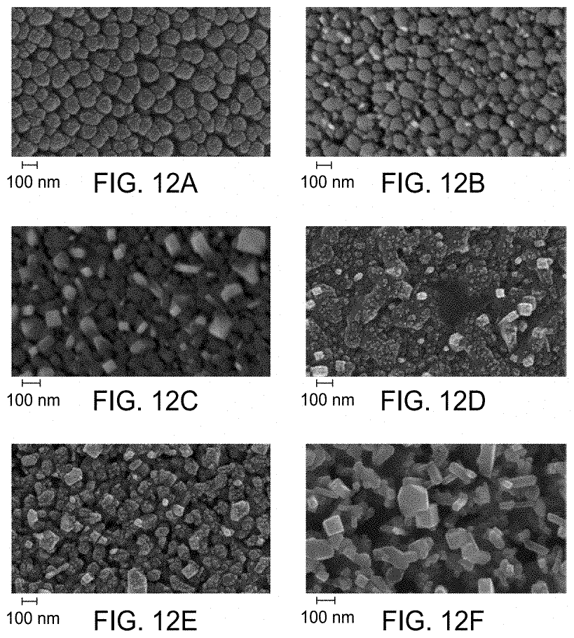

FIGS. 11A-11B are graphs illustrating x-ray photoelectron spectroscopy (XPS) measurements of a film deposited from a sputtering target formed from the LRCO material. XPS analysis was carried out to investigate the oxidation state of the transition metal within as-deposited LRCO thin films (thin films before any anneal). FIG. 11A shows the entire elemental survey of LRCO films on the surface. FIG. 11B illustrates the Co 2p region of the survey of FIG. 11A. The Co 2p spectra, as shown in FIG. 11B, show two peaks representing binding energy of about 780.9 eV (Co 2p_{3/2}) and about 796.3 eV (Co 2p_{1/2}), separately, which match well with LCO and can be attributed to the presence of Co in the +3 charged state. FIG. 11B illustrates a high resolution scan of the O 1s region of the survey of FIG. 11A. FIG. 11D illustrates a high resolution scan of the Ru 3p region of the survey of FIG. 11A. The two Ru 3p core peaks appearing in FIG. 12D with binding energy of 486.7 eV (3p_{1/2}) and 464.0 eV (3p_{3/2}) indicate that the Ru oxidation state is 4+.

To further investigate morphology differences of LRCO thin films deposited from the LRCO-2 target at a target-sample distance of 5 cm as a function of annealing temperature, top-down and cross-sectional SEM images were compared in FIGS. 12A-12F. FIG. 12A illustrates the morphology of an LRCO thin film as deposited and without annealing. FIG. 12B illustrates the morphology of an LRCO thin film after a one hour anneal at 300° C. FIG. 12C illustrates the morphology of an LRCO thin film after a one hour anneal at 400° C. FIG. 12D illustrates the morphology of an LRCO thin film after a one hour anneal at 500° C. FIG. 12E illustrates the morphology of an LRCO thin film after a one hour anneal at 600° C. FIG. 12F illustrates the morphology of an LRCO thin film after a one hour anneal at 700° C.

At annealing temperatures of 300 and 400° C. (FIGS. 12B and 12C), a small number of crystalline grains appeared on the surface, but most of the remaining were spherical particles similar to that of as-deposited films (FIG. 12A). Starting from 500 to 600° C. (FIGS. 12D and 12E), those remaining columnar surfaces begin to crystallize. At 700° C. (FIG. 12F), all thin film surfaces have fully crystalized and the particles exhibit polyhedral morphology with an average size of about 50 nm to about 100 nm.

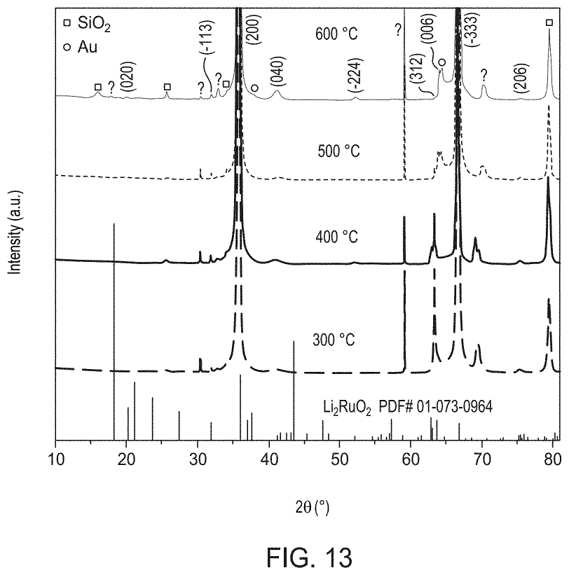

Thin-film XRD patterns were presented in FIG. 13 to make a comparison among the different annealing temperatures. Since the substrates were gold-coated thermal oxide silicon wafers, gold and silicon oxide (SiO₂) diffraction peaks (indexed from a fitted PDF card database) were also present in the diffractograms. As the temperature increases, most diffraction peaks intensified, owing to enhanced crystallinity which can be demonstrated by SEM in FIGS. 12A-12F. At about 60° to about 65°, (312) and (006) Bragg peaks became more dissociated as the annealing temperature increased. It is worth noting that some unknown peaks (labeled by “?”) cannot be assigned to LRO, LCO, gold, or silicon oxide phases. These peaks may be caused by impurity phases, such as Co₃O₄ or RuO₂, due to high temperature annealing. Another possibility is that lithium reacts with gold at high temperatures, leading to the existence of impurities. Further, the morphologies described herein correspond to films deposited at a sputtering distance of 5 cm, but a sputtering distance of 10 cm may lead to different morphologies.

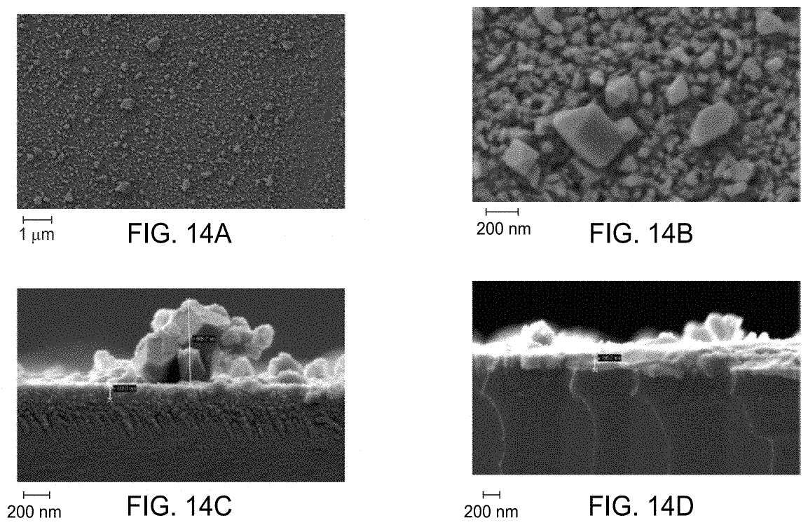

SEM of annealed LRCO-2 thin films (450° C. for 3 h) are shown in FIGS. 14A-14D. FIGS. 14A and 14B are plan views of SEMs of the annealed LRCO-2 thin films. FIGS. 14C and 14D are cross-sectional SEMs of the annealed LRCO-2 thin films. Many nanoscale particles appeared after annealing and the average size can range from about 50 nm to about 650 nm (FIG. 14C), which largely increase the possibility of shorting when depositing a LiPON layer as the electrolyte. Surprisingly, the total thickness of LRCO-2 thin films decreased from about 300 nm to about 200 nm, as shown in FIG. 14D. Some highly crystalized areas were even thinner, such as about 120 nm (FIG. 14C). Heterogeneous crystalline grain size distribution is non-favorable and will give rise to non-uniform Li ion transport during cycling, leading to low Coulombic efficiency and fast capacity fading. One potential explanation is a large chemical compositional discrepancy between the target and deposited film when deposited at these larger distances due to the loss of low atomic mass lithium during the sputtering process. This may lead to lithium deficiencies in the film that give rise to impurity phases, such as RuO₂ or Co₃O₄, during subsequent annealing steps.

The LRCO thin films as discussed herein are fully functional, reversible cathodes and have substantial capacity in the as-deposited, unannealed state. The electrochemical characterization and energy storage performance tests discussed herein are therefore focused primarily on amorphous thin films of LRCO. There is practical motivation for utilizing as-deposited/unannealed thin films as well. Utilizing as-deposited thin films eliminates the annealing steps and significantly broadens substrate compatibility while reducing production costs. For electrochemical characterization described herein, a 250 nm-thick thin film cathode was deposited by sputtering the LRCO-2 target onto a platinum current collector supported on a quartz substrate. One micrometer of LiPON and nominally 2 micrometers of Li were sequentially deposited on top of the LRCO film. The thin film cell was cycled between 2.0 V and 4.5 V at a rate of 20 μA/cm² and the cathode area was used to compute current density. The cycling between 2.0 V and 4.5 V at a rate of 20 μA/cm² is described herein as a first charging pattern. A stable capacity of 105 μAh/cm²-μm could be reversibly accessed over 20 charge/discharge cycles. This is a substantial improvement over LiCoO₂ cathodes, which provide a capacity of 67.5 μAh/cm²-μm. Further, LCO films are thermally annealed at temperatures exceeding several hundred degrees Celsius to fully crystallize the LCO microstructure and obtain optimal energy storage performance.

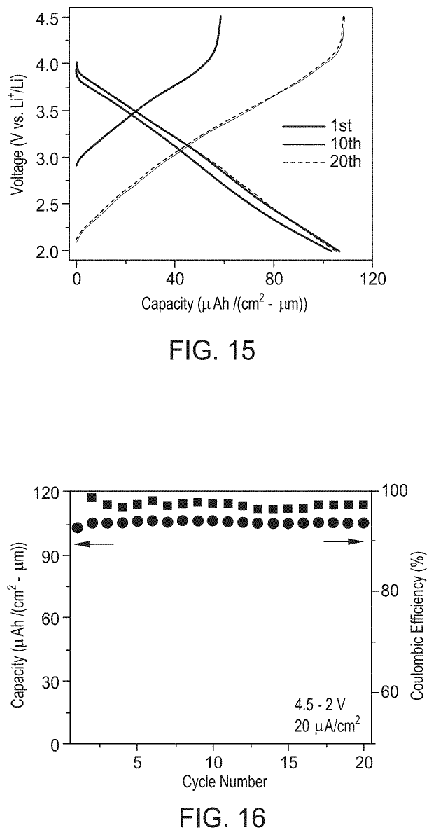

The voltage profiles and cycle capacities of the as-deposited LRCO-2 are provided in FIG. 15 and FIG. 16, respectively. FIG. 15 is a graph illustrating charge and discharge curves of assembled lithium ion cells with an LRCO cathode material after cycling using a first charging pattern. The charge and discharge curves of FIG. 15 are provided for the 1^{st}, 10^{th}, and 20^{th} cycles. FIG. 16 is a graph illustrating cycling stability curves of the assembled lithium ion cells with the LRCO cathode material over 20 cycles using the first charging pattern. As illustrated in FIG. 16, the average Coulombic efficiency over the 20 cycles is 97.6% (excluding the first cycle) and the discharge capacity was 105.5 μAh/cm²-μm. During testing, the temperature was maintained at about 25° C.

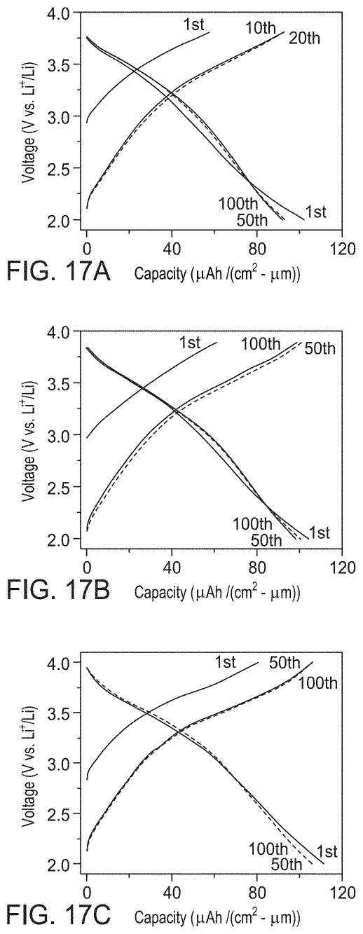

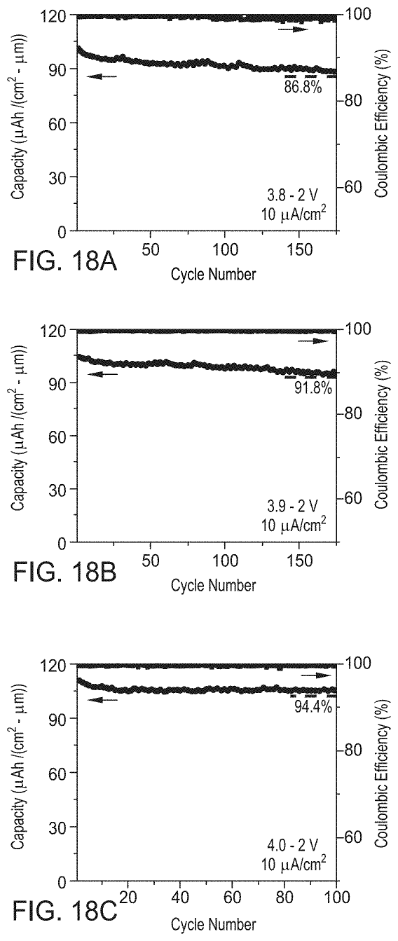

The Coulombic efficiency, sometimes referred to as reversibility, of the cells can be further improved by charging the LRCO to lower potentials at lower current densities. FIGS. 17 and 18 present the charge/discharge voltage profiles and cycling performance as a function of charge potential. In the first charge to 3.8 V, LRCO has a capacity of 57.5 μAh/cm²-μm. Discharging from 3.8 to 2.0 V with a current density of 10 μA/cm2, the thin film battery delivers a first discharge capacity of 101.3 μAh/cm²-μm (FIG. 17A). The lower first charge capacity likely results from the higher sputtering target-substrate distance (10 cm), whereby the loss of the lightest Li atoms during sputtering leads to a Li-deficient LRCO thin-film composition. After lithiation in the first discharge, the charge capacity recovers and matches the discharge capacity. The suppressed first charge capacity is observed for all charge potentials (FIGS. 17B and 17C). Over 175 cycles at the 3.8 V charge voltage, the average coulombic efficiency was 99.5% with a capacity retention of 86.8% (FIG. 18A). Increasing the charge potential to 3.9 V yields a first discharge capacity of 104.2 μAh/cm²-μm, owing to more Li ions being intercalated and de-intercalated (FIG. 18B). Capacity retention was further increased to 91.8% over 175 cycles (94.4% at the 100th cycle) with a higher average coulombic efficiency of 99.8% (FIG. 18B). With a charge cut-off voltage of 4.0 V, the discharge capacity further increases to 111.7 μAh/cm²-μm, but the capacity retention over 100 cycles remains the same (FIGS. 18B and 18C).

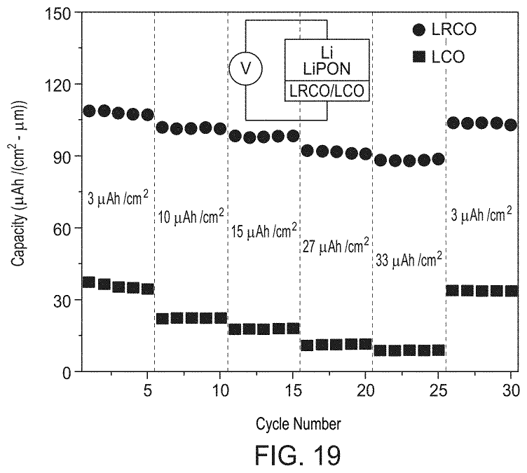

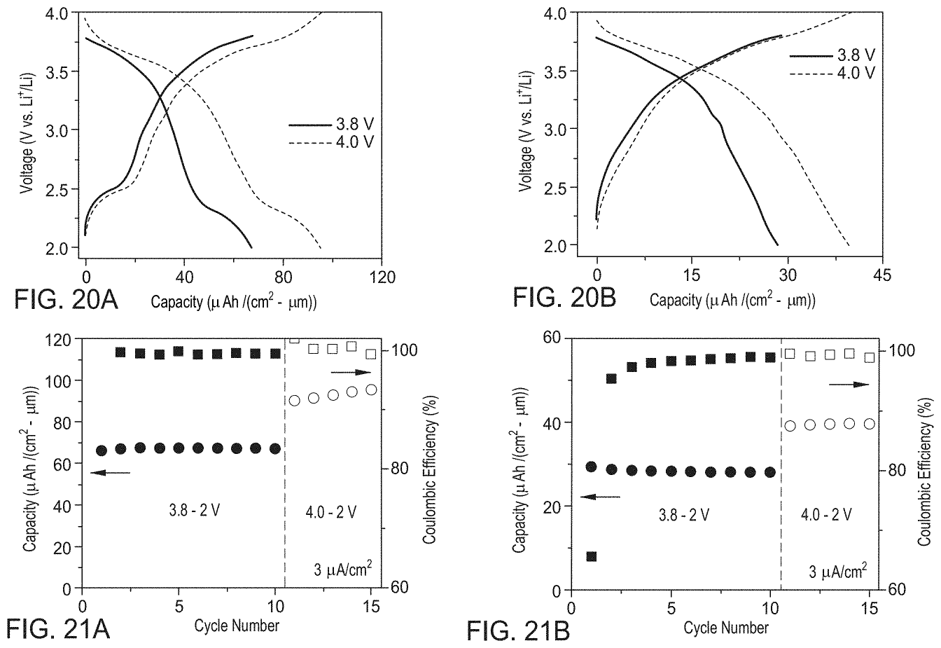

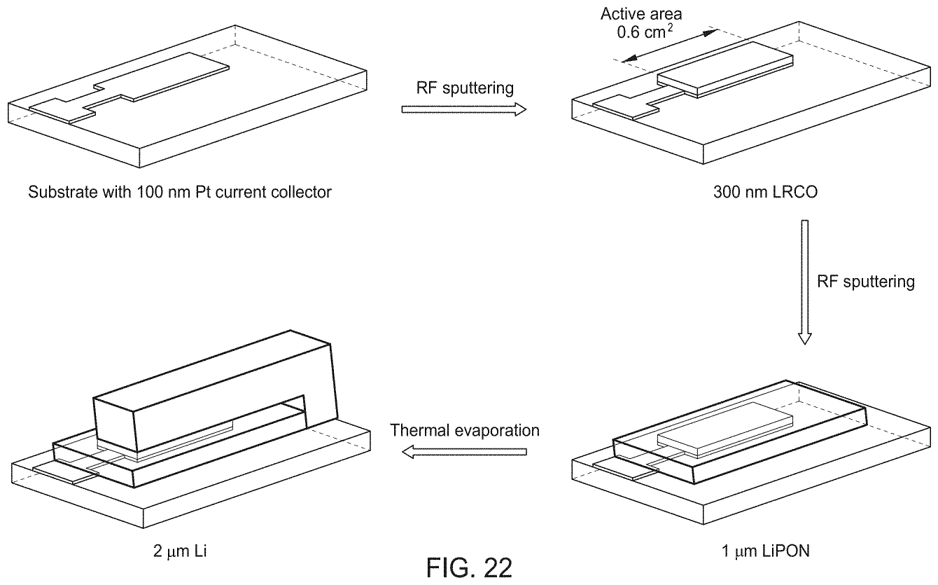

As shown in FIG. 19, the LRCO thin film cathodes also demonstrate exceptional rate performance. FIG. 19 illustrates the rate performance of an LRCO thin film battery with a 300 nm thick as-deposited cathode. Discharge capacity was measured stepwise while incrementing the current densities 3 to 10, 15, 27, and 33 μA/cm², followed by a decrease back to 3 μA/cm² to further assess reversibility. Each rate includes five cycles in the voltage ranges from 2.0 to 3.9 V (LRCO) and 3.0 to 4.2 V (LCO). Even at a current rate of 1C (33 μA/cm²), a specific capacity of 88.8 μAh/cm²-μm can be accessed in LRCO, compared to 108.5 μAh/cm²-μm at 0.1C—representing a capacity utilization of 81.8%. As expected, discharge capacity is strongly dependent on the current density, but LRCO's capacity recovery at 0.1C (3 μA/cm²) after the rate testing is further indication of the stability of the LRCO cathode. On the other hand, as-deposited LCO provides approximately one-third the specific capacity of as-deposited LRCO thin films (37.1 vs. 108.4 μAh/cm²-um at 3 μA/cm²). Moreover, when current density was increased to 33 μA/cm², the discharge capacity of LCO dropped to only 8.6 μAh/cm²—representing a relatively low capacity utilization of 25.6% (compared to >80% in LRCO). Given its superior specific capacity and rate performance, LRCO is an excellent candidate that provides facile lithiation and de-lithiation, low resistivity, and high volumetric capacity. The challenges associated with conventional Li₂RuO₃ cathodes, such as oxygen gas evolution and voltage decay, can be addressed in thin film formats by mixing with LiCoO₂ and limiting the charge potentials.

The ability to obtain significant capacity in as-deposited LRCO allows for the formation of a thin film battery without thermal annealing. Thermal annealing adds significant processing cost and time to the preparation of LCO thin film cathodes. Typically, LCO films are annealed at temperatures in excess of 500° C. The thermal annealing requires that the substrate is also thermally stable. Typical substrates are inorganic materials, such as aluminum oxide (Al₂O₃) or quartz. In this initial demonstration of LRCO thin films, quartz substrates were used, however, the methods disclosed herein also include thin film preparation in the absence of annealing on flexible, lower melt-temperature substrates such as a polymer substrates.

In some embodiments, thermal annealing is used to crystallize the as-deposited LRCO, which is expected to enhance the specific energy, Li⁺ diffusivity and (de)lithiation potentials. In some embodiments, LRCO thin films were annealed at 450° C. and 650° C. for 3 hours. The annealed LRCO thin films are reversible and demonstrate stable charge capacities as shown in FIGS. 20A-20B and 21A-21B.

FIGS. 20A-20B illustrate charge and discharge curves of assembled lithium ion cells with an LRCO cathode material after annealing the LRCO cathode material at various temperatures. In FIGS. 20A-20B the LRCO thin films were charged between 2.0 V and 3.8 V vs. Li/Li⁺ at 3 μA/cm² as well as between 2.0 V and 4.0 V vs. Li/Li⁺ at 3 μA/cm². In FIG. 20A, the LRCO thin film cathode was annealed at 450° C. for 3 hours. In FIG. 20B, the LRCO thin film cathode was annealed at 650° C. for 3 hours. During cycling of the LRCO cathode thin film batteries, the temperature was maintained at 25° C.

FIGS. 21A-21B illustrate cycling stability curves of the assembled lithium ion cells with the LRCO cathode material after annealing the LRCO cathode material at various temperatures. In FIG. 21A, the LRCO thin film cathode was annealed at 450° C. for 3 hours. In FIG. 21B, the LRCO thin film cathode was annealed at 650° C. for 3 hours. The LRCO thin film battery was charged to 3.8 V for the first 10 cycles and charged to 4.0 V for the next 5 cycles. During the change in the upper charge limit, the discharge potential remained fixed at 2.0 V. During cycling of the LRCO cathode thin film batteries, the temperature was maintained at 25° C.

As illustrated in FIGS. 20A-20B and 21A-21B, the annealed thin films have lower capacities than the as-deposited, unannealed films previously described. The lower capacities are attributed to the lithiation potential shifting to higher potentials in the crystalline state. For both annealing temperatures (450° C. and 650° C.), increasing the charge potential to 4.0 V results in substantial specific capacity/specific energy gains. As discussed with respect to FIG. 14A-14D, heterogeneous crystal particles grew after annealing. The heterogeneous crystal particles after annealing vary in size from about 50 nm to about 600 nm and hamper effective Li ion transport and reduce Coulombic efficiency. The larger particles lead to large volume changes during cycling, followed by structural collapse and potential shorting. The large particle size may be why annealed cathodes show low Coulombic efficiency, increased capacity fading and ultimately short-circuit.

### EXAMPLE 2

Lithium ruthenium cobalt oxide (LRCO) cathode materials with a chemical formula of (1−x)Li₂RuO₃+xLiCoO₂+yLi₂O where Y is between about 0.05 and 0.6 and X is between about 0.05 and 0.5 were used to prepare energy-dense cathode thin films at low temperatures. The LRCO thin films were prepared by RF magnetron sputtering and were shown to be smooth, uniform, and electrochemically active without further thermal annealing, enabling the successful fabrication and operation of thin film batteries on flexible thermoplastic substrates. Compared to lithium cobalt oxide (LCO) films with a specific capacity of 39 μAh cm⁻² μm⁻¹, LRCO provide a high discharge capacity of 110 μAh cm⁻² μm⁻¹ at a 0.3 C rate and greater than 92% capacity retention over 150 cycles. This discharge capacity exceeds even the optimized, near-theoretical capacity of annealed, polycrystalline LCO (67 μAh cm⁻² μm⁻¹).

LRCO was prepared by conventional solid-state synthesis. Li₂CO₃ (Alfa Aesar, 99.9% purity, 35 wt. % excess), RuO₂ (Alfa Aesar, 99.9% purity), and CoCO₃ (Alfa Aesar, 99.9% purity) precursors were weighed according to the desired stoichiometry ((1−x)Li₂RuO₃−xLiCoO₂−yLi₂O), mixed with anhydrous acetone (Alfa Aesar), and ground in a planetary ball mill (DECO, PBM-V-0.4L). Excess Li₂CO₃ was included to compensate for Li loss during high temperature annealing and/or subsequent sputtering. The powder mixture was heated at a rate of 2° C./min in a muffle furnace (air atmosphere) to a temperature of 1000° C., held for 12 hours, then cooled under ambient conditions.

A two-inch sputtering target for thin film deposition was prepared by high temperature sintering of the synthesized LRCO powder. LRCO powder agglomerates were first ground using a mortar and pestle. The fine powders were then mixed with a 5 wt. % solution of polyethylene oxide (PEO) in N,N-dimethylformamide (DMF) binder solution, and the mixture was then heated to 70° C. to remove the DMF solvent. The LRCO and PEO binder mixture was cold pressed in a two-inch (5.08 cm) diameter die at 48 MPa for 5 mins. The pellet was then removed from the die, placed in a clean alumina dish, and sintered at 900° C. for 5 hours in a muffle furnace. After the sintered target fully cooled, it was attached to a copper backing plate (OHFC) using silver-filled, vacuum grade epoxy (Dynaloy, KL-325K). The target was cured at 70° C. under vacuum before installation in the sputtering chamber.

LRCO and LCO thin films were fabricated via RF magnetron sputtering in a custom-built vacuum deposition chamber. LCO sputtering target (99.9% purity) with a size of (2.00″ (5.08 cm) diameter×0.125″ (0.3175 cm) thick) was purchased from Kurt J. Lesker. Process parameters for the RF magnetron sputtering are provided in Table 1. Optical grade fused quartz slides (AdValue Technology, FQ-S-001, 2.54×2.54×0.1 cm) were used as substrates for all thin-film battery assembly. Before thin film cathode deposition, 100 nm-thick Pt, as cathode current collector, was deposited via direct current (DC) sputtering (Denton Vacuum DESK-II DC Sputtering System). Thin film cathodes with an area of 0.6 cm² were typically deposited to 300 nm thickness, confirmed by scanning electron microscopy (SEM).

TABLE 1
Deposition parameters for RF magnetron
sputtering thin-film cathode.

| Parameter | Value | |
|---|---|---|
| Base pressure | 5 × 10⁻⁷ | Torr |
| Working pressure | 15 | mTorr |
| Power | 70 | W |
| Substrate-target distance | 10 | cm |

| | |
|---|---|
| Working gas flow rate | Ar: 4 sccm, O₂: 1 sccm |

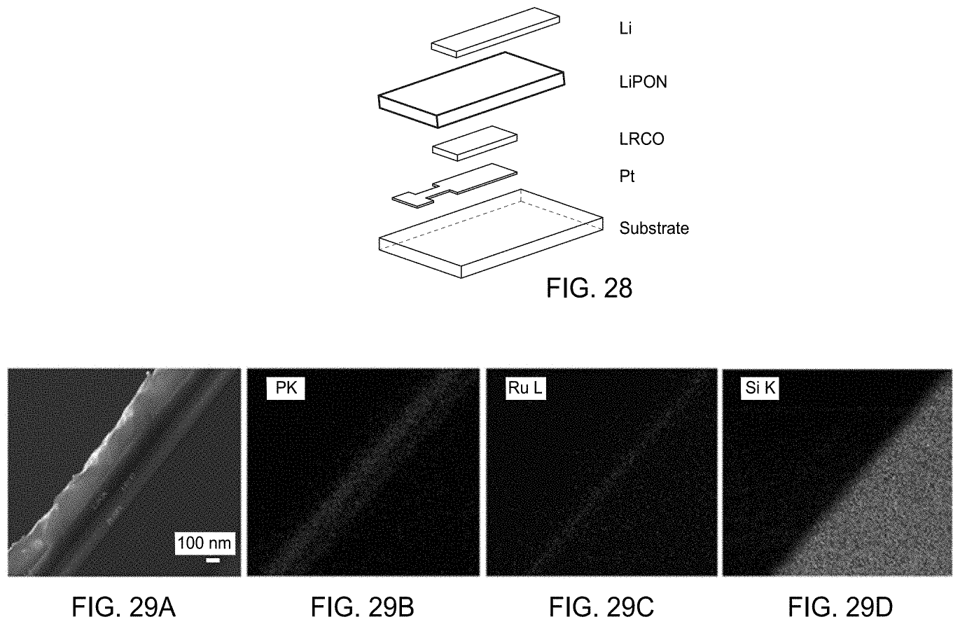

Thin films (1 μm and 5 cm²) of lithium phosphorous oxynitride (LiPON) were directly deposited on top of the cathode layer by radio frequency (RF) magnetron sputtering of a 2-inch (5.08 cm) Li₃PO₄ powder target (99.95%, Kurt J. Lesker) in ultrapure N₂ atmosphere. The custom-built sputtering chamber was pumped to ˜5×10⁻⁷ Torr via a mechanical diffusion pump before deposition. Key deposition parameters were a forward power of 90 W, a nitrogen gas flow rate of 5 sccm, an operating pressure of 20 mTorr, and a target-substrate distance of 5 cm. 2-μm-thick Li metal, as anode and current collector, was thermally evaporated in custom vacuum chamber with a base pressure of ˜6×10⁻⁷ Torr. Quartz crystal monitor (QCM) was used to in-situ monitor Li deposition rate. A schematic illustration of the thin film battery fabrication process is shown in FIG. 28.

### Material Characterization

Inductively coupled plasma-mass spectrometry (ICP-MS) was performed using Perkin Elmer NexION 200 to identify the chemical composition of the LRCO target. To determine the structure of LRCO powders and thin films, powder X-ray diffraction (XRD) and thin-film XRD were conducted using a Rigaku Synergy-S diffraction system and a Bruker D8 Advance system with Cu Kα microfocus X-ray source, separately. XRD patterns were refined via MDI Jade 9 software. X-ray photoelectron spectroscopy (XPS) was performed using a Krato Axis Ultra DLD XPS system with a monochromatized Al Kα source at 15 kV and 10 mA. Survey scans were conducted from 1200 to 5 eV with a 1 eV step and 160 eV pass energy. For calibration, the aliphatic C 1s peak was assigned to 284.6 eV. Ten high-resolution scans were employed for O 1s, Ru 3d, and Co 2p with a pass energy of 20 eV. Detailed peak deconvolution was analysed via CasaXPS software. For post-mortem analysis, the cell was carefully disassembled in an Ar-filled glove box. All samples were put into a hermetically sealed plastic bottle, and then transferred to various analysis systems. Scanning electron microscopy (SEM) and energy dispersive X-ray spectroscopy (EDS) were performed on a ZEISS Crossbeam 340 FIB-SEM system using an accelerating voltage of 7.5 kV. For analysis of the samples' cross-section, sample substrates were fractured by hand.

### Electrochemical Characterization

Thin-film batteries were cycled inside an Ar-filled glovebox under various charge potentials using a battery cycler (BT-2043, Arbin Instruments). The electrode area was defined by the geometric area of the cathode side. Cyclic voltammetry was conducted from 2.0 V to 3.9 V reversibly with a scanning rate of 0.1 mV/s. Rate performance tests (5 cycles as an increase period) were employed at 3, 10, 15, 27, 33, back to 3 μA/cm², 2.0-3.9 V (LRCO) and 3.0-4.2V (LCO) vs. Li/Li⁺ and at 25° C.

### Structural and Morphological Characterization

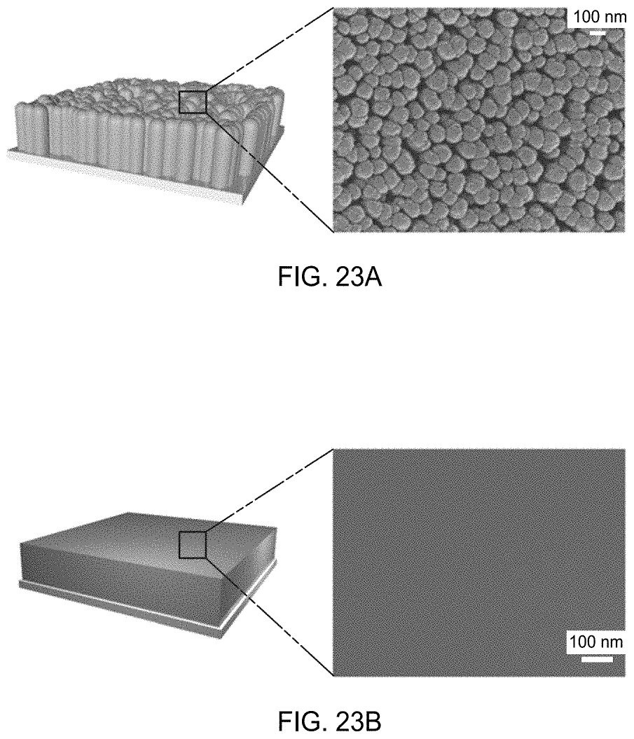

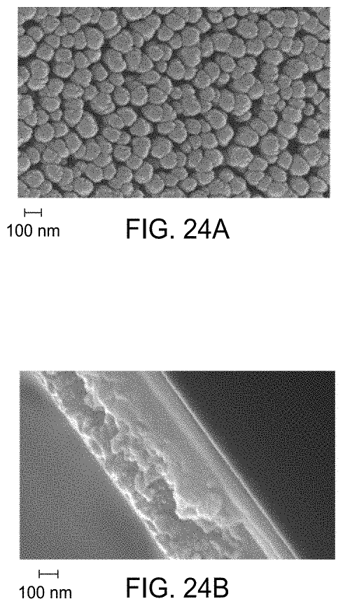

For structural and morphological characterization, LRCO thin films were first prepared on flat, model Si wafer substrates. The Si wafers were coated with a 300 nm-thick thermal oxide layer to prevent potential Li interdiffusion into Si during sputtering. FIGS. 23A and 23B provide conceptual depictions of the LRCO film morphologies based on corresponding SEM characterization. The film morphology is strongly dependent on the sputtering target-substrate distance. A typical distance of 5 cm was first used when sputtering the LRCO thin films, resulting in the morphologies shown in FIG. 23A. Surprisingly, LRCO deposits into columns separated by voids, which may increase the possibility of short circuiting in a completed thin film battery due to incomplete coverage by the thin film electrolyte. Also, the columnar morphology increases contact area and interfacial non-uniformity between electrolyte and cathode, resulting in nonuniform Li ion transport through the cathode. Increasing the sample distance from 5 cm to 10 cm during deposition, results in isotropic, smooth, featureless films as shown in FIG. 23B; the columnar morphology disappears (FIG. 24A-B). The longer sputtering deposition distance reduces the kinetic energy of sputtered atoms by way of atom-atom collisions, leading to moderate surface temperature and preventing crystallization during the deposition. Though the deposition rate was reduced from 20 nm/min (at a 5 cm distance) to 5 nm/min (at 10 cm), a featureless cathode surface is beneficial and enables more uniform Li ion flux transport (FIG. 26).

Returning now to FIGS. 24A-24B, two views of scanning electron micrographs of a thin film deposited from a sputtering target formed from the LRCO material are depicted. The first view of FIG. 24A is a plan-view of the thin film deposited using an LRCO-2 sputtering target at a sputtering target to substrate distance of 5 cm. The second view of FIG. 24B is a cross-sectional view of a thin film deposited from an LRCO-2 sputtering target at a sputtering target to substrate distance of 5 cm. As noted above, an unexpected finding is the dependence of deposited thin film morphology on the distance between the substrate and the target during sputtering. As shown in FIGS. 24A-24B, at a sputtering distance of 5 cm, the film develops a columnar/particulate morphology that results in significant film roughness. However, at 10 cm, the film is uniform, smooth, and lacks obvious surface topography. Functioning cathode thin films can be prepared at both distances. For the electrochemical data of the thin film batteries included herein, 10 cm was used as the sputtering distance.

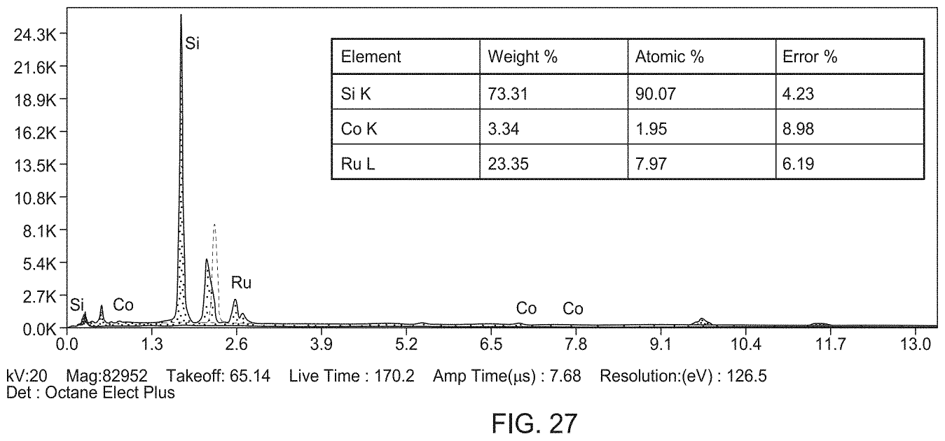

The LRCO target was prepared based on Li-rich solid solution of ((1−x)Li₂RuO₃−xLiCoO₂−yLi₂O), where x is content for Co and y is the ratio for excess Li in the target. The chemical composition of the LRCO target of 0.79Li2RuO₃-0.18LiCoO₂-0.66Li₂O was confirmed by ICP-MS (see Table 2). For liquid coin cells, a slurry was prepared by adding a binder solution containing 10 wt. % PVDF in N-methyl-2-pyrrolidone (NMP) solvent to the LRCO powder mixture containing 80 wt. % active material and 10 wt. % Super P carbon. The slurry was cast on an Al foil current collector and dried under vacuum at 100° C. overnight before cell assembly. Metallic Li foil (1.9 mm×0.75 mm, 99.9%, Alfa Aesar) was scraped, rolled and cut into a disc with a diameter of 1.43 cm and put on a microporous separator of slightly larger diameter (glass fiber) which acted as a spacer to define the electrode separation. Electrolyte used was 100 μl of 1.0 M LiPF₆ in 1:1:1 EC:EMC:DMC (Gotion). The coin cells were cycled from 2.0 to 4.5 V using a battery cycler (BT-2043, Arbin Instruments). The first two cycles were set at a 0.02 C rate as the formation period. Cell temperature was controlled at 25° C. Excess Li was added to the target to compensate for Li loss during high temperature calcination of the sputtering target and long-distance sputtering deposition. Increasing the substrate-target distance is expected to reduce the lithium to transition metal ratio, since Li is the lightest metal element, resulting in a lower sputter yield in the final film composition. A Ru:Co atomic ratio of 4:1 was confirmed by EDS (provided in FIG. 27), indicating consistency between the target and sputtered sample. Therefore, a general composition of (0.8Li₂RuO₃-0.2LiCoO₂-xLi₂O) was assigned to all LRCO thin film cathode prepared in this work.

TABLE 2
ICP-MS Results of LRCO Sputtering Target

ICP-MS results

| LRCO | Composition | Li | Ru | Co |
|---|---|---|---|---|
| Target | Li_{3.09}Ru_{0.79}Co_{0.18}O_{3.4} | 3.09 | 0.79 | 0.18 |

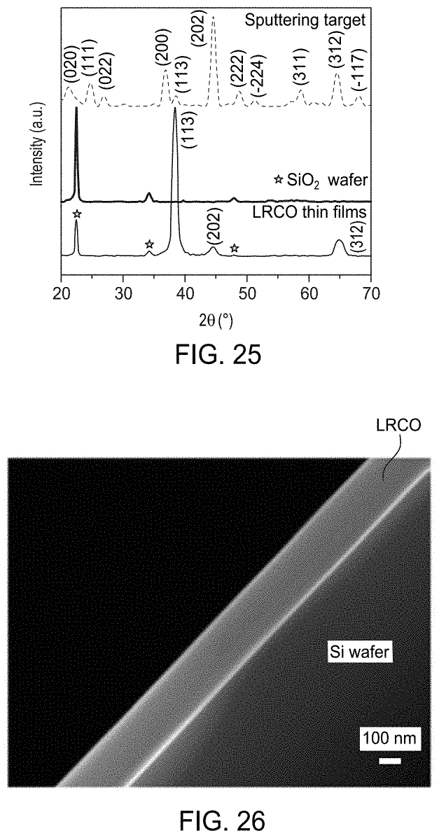

To investigate the crystallinity and microstructure of the LRCO thin films, XRD was conducted on the smooth, featureless films (deposited at 10 cm distance). X-ray diffractograms of the precursor LRCO powders for the sputtering target, LRCO thin film, and substrate (thermal oxide on Si wafer) are provided in FIG. 25. XRD spectra of the LRCO target were indexed with monoclinic Li₂RuO₃ structure (PDF#01-072-4645) and hexagonal LiCoO₂ structure (PDF#01-073-0964, diffraction data publicly available at International Center for Diffraction Data database, icdd.com). Due to solid solutions of Li₂RuO₃ with space group C2̅/c and LiCoO₂ with space group R3̅m, the synthesized LRCO target possesses a hexagonal α-NaFeO₂ type structure, wherein six RuO₆ octahedral interstice surround one LiO₆ octahedra, thereby forming a LiRu₆ unit in TM layers. Crystalline planes (020) and (111), which are deemed as superlattice peaks, indicate a high stacking level of TM layer along c-axis of monoclinic Li₂RuO₃ structure. For LRCO thin films, three diffraction peaks (starred) are assigned to the SiO₂ layer on the substrate and all remaining peaks can be indexed to corresponding characteristic reflections of LRCO. Broad amorphous diffraction peaks do not appear prominently in the diffractogram, and three LRCO crystalline planes can be assigned to the target, including (113), (202) and (312). Though the SEM suggests that the film is amorphous, the sharp (113) reflection found in the LRCO film indicates at least partial crystallinity of the as-deposited thin films (no post-deposition annealing was done). The crystallinity presumably results from accumulated heat on the substrate during the sputtering process. This thermal energy facilitates the rearrangement of Li, Ru, Co and O absorbed atoms. Compared to the fully crystalline LRCO sputtering target, the wider full width at half maximum of (202) and (312) planes suggests the nanocrystalline LRCO phase in the films, demonstrating the mixed composition of amorphous and nanocrystalline structure of as-prepared LRCO thin films.

### Electrochemical Characterization of As-Deposited LRCO in TFBs

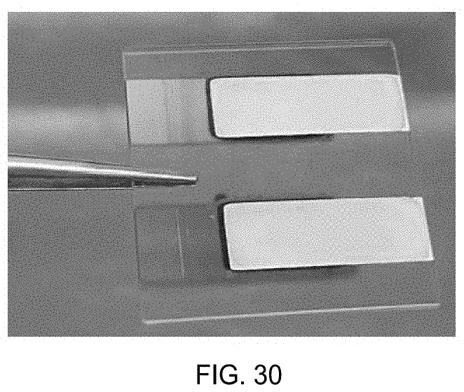

LRCO TFBs were successfully fabricated by sequential deposition of films of Pt, LRCO, LiPON, and Li metal onto a quartz substrate, as shown by the 3D schematic in FIG. 28 and the SEM micrographs in FIGS. 29A-29D. A digital photograph of a thin film cell is provided in FIG. 30. An approximate two micrometer-thick thermally evaporated Li metal anode was the last layer deposited on the TFB and was not coated with a protective layer. Owing to unavoidable atmospheric exposure during sample transfer, the Li surface was oxidized and became nonconductive, resulting in charging in the middle of the Li layer observed in the SEM micrograph. Below this Li metal layer, SEM and corresponding phosphorus mapping clearly reveal a dense and intact LiPON layer with a thickness of 1 μm. EDS maps of ruthenium (FIGS. 29A-29D) combined with SEM micrographs demonstrated a featureless layer of 300 nm-thick LRCO thin-film cathodes. EDS mapping intensity of Ru was not as strong as that of P or Si because LRCO films were the thinnest, but the film boundaries can be distinguished. Pt layers (100 nm-thick) deposited via direct current (DC) sputtering served as cathode current collectors. An EDS map of the Si clearly reveals the position of the quartz substrate.

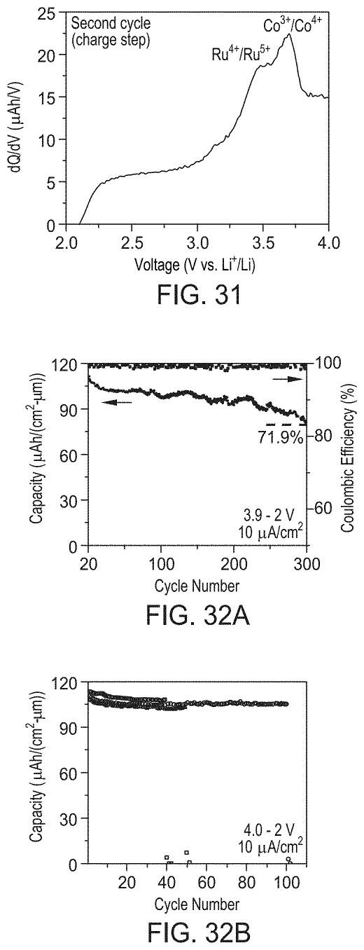

For each charge potential, the cells exhibit sloping voltage profiles (FIGS. 17A-17C). The lack of flat voltage plateaus characteristic of two-phase reactions is expected given the amorphous/nanocrystalline nature of the LRCO films. Using differential capacity analysis (FIG. 31), the contribution of the Ru⁴⁺/⁵⁺ oxidation couple is resolved with a peak at ˜3.6 V; it is responsible for most of the cathode capacity. The oxidation peak of Co³⁺/⁴⁺ is also revealed at 3.7 V. This data demonstrates that both Ru and Co redox contribute capacity to the cathode.

While all cells demonstrate excellent performance over the first 100 cycles, extended cycling reveals important distinctions in failure modes of LRCO cathodes charged to 3.9 and 4.0V (FIG. 31). The cell charged to 3.9V vs. Li/Li⁺ showed a capacity retention of 71.9% over 300 cycles (FIG. 32A), further demonstrating the stability of LRCO at this potential. Degradation of the Li metal film over the long-term test in the glovebox (over 3 months) is partially responsible for the capacity decay. The Li metal was not coated with a protective layer, which is key to achieving stable cycling over extended timeframes and/or thousands of cycles, and chemical reactions of the Li metal were visually apparent in the imperfect atmosphere of the glovebox. At a charge potential of 4.0 V, extended cycling to 300 cycles was attempted. Several cells were fabricated and charged to 4.0 V, and abrupt failure rather than slow capacity decay was observed in each one. Representative cycling of three cells is presented in FIG. 32B, which includes the champion cell data from FIG. 18B. Each of these cells fail suddenly through a short-circuit, suggesting that the integrity of the LiPON layer has been compromised. One possibility is that structural instability of the cathode combined with potential molecular oxygen release at higher potentials leads to structural collapse of the films, fracturing the LiPON. In these materials, high potential charging may enlist two oxidation processes: the anionic redox reaction of O²⁻/O²⁻, followed by the irreversible formation of molecular oxygen. The high capacities of anion-redox active cathode materials are derived from cumulative cationic and anionic redox process. However, the appearance of peroxo/superoxol-like species during anionic redox reaction leads to the nucleation of a disordered phase, which further irreversibly modifies oxygen crystal network, which evolves on the following discharge step, causing permanent damage to the cathode structure. While clear evidence of the oxygen release is not observed in the profiles, possibly due to nanocrystalline nature of the film, the key conclusion from the cycling is that 3.9V provides stable cycling with state-of-the capacities that are superior to state-of-the-art thin film materials (see FIG. 36). Charging to 4V and beyond may extract more capacity at the expense of stability.

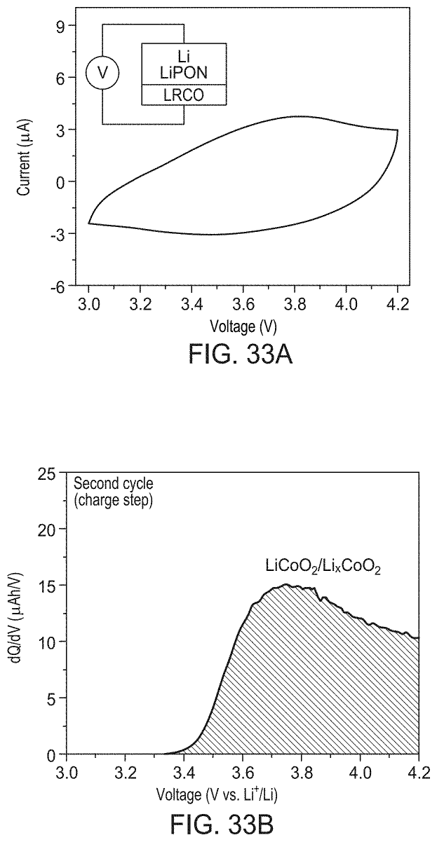

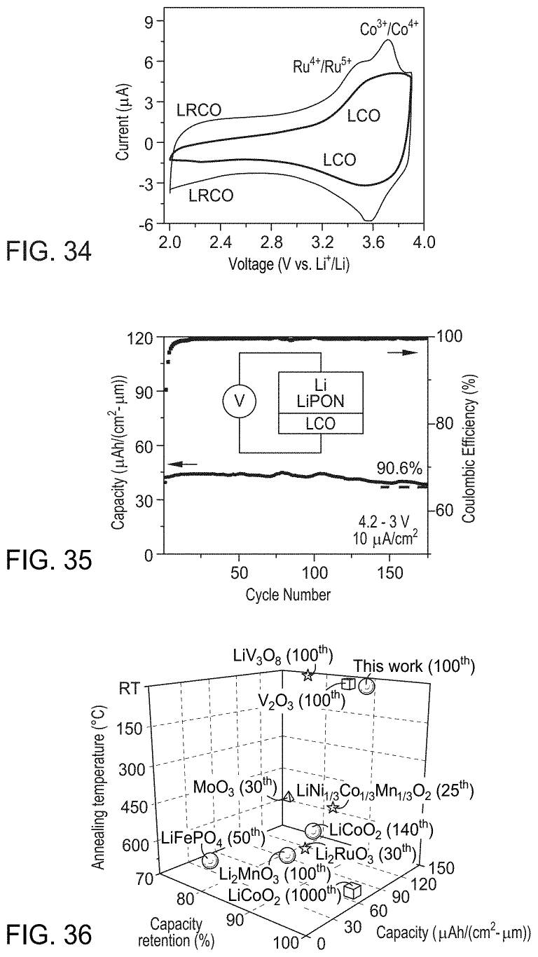

To further understand the contribution of both Co and Ru redox in the cycling of cathode, additional electrochemical characterization of as-deposited LRCO was conducted. For comparison, unannealed LiCoO₂ (LCO) thin films were also prepared and characterized. The cyclic voltammograms (CV) of both LRCO and LCO at a scanning rate of 0.1 mV/s is provided in FIG. 34. A small peak at ˜3.5 V can be assigned to redox couple of Ru⁴⁺/Ru⁵⁺ and another sharp peak at ˜3.7 V corresponds to oxidation of Co from 3+ to 4+. The oxidation of Ru and Co compensate charge neutrality as Li is extracted from the cathode during charge. During cathodic scans, these two reduction peaks related to Co⁴⁺/Co³⁺ and Ru⁵⁺/Ru⁴⁺ merged into a broader peak range from ˜3.8 to 3.5 V. Importantly, indication of oxygen oxidation is absent from the voltammogram. Oxygen oxidation is expected to appear if anodic scan extends above 4.0 V, which would be potentially accompanied with formation of O₂ gas, irreversibly destroying the cathode structure or compromising the integrity of the thin film battery. Therefore, an upper limit of 3.9 V vs. Li/Li⁺ is considered a safe limit for these batteries—it provides nearly the same capacity as a 4.0 V charge but also ensures that only redox reactions of transition metals are occurring. As a reference, LCO thin films exhibit similar redox trends that starting from ˜3.5 V, a broad anodic peak is attributed to de-intercalation of Li ions. The differential charge capacity data in FIG. 33B indicates de-lithiation of as-deposited LiCoO₂ can provide charge capacity of 8.6 μAh. The reduction peak at ˜3.6 V can be assigned to Li ion intercalation (FIG. 34). Furthermore, the CV curve of as-deposited LCO which shows the voltage range from 3.0 to 4.2 Vat a scan rate of 0.1 mV/s could be found in FIG. 33A, exhibiting a sluggish electrochemical activity and lower current densities compared to LRCO.

In addition to the CV, TFBs with 300 nm-thick as-deposited LCO films were also cycled; the results are reported in FIG. 35. Under the same current density as of LRCO, LCO reveals comparable capacity retention of 90.6% but relatively low specific capacity of 38.6 μAh/cm² after 175 cycles. This performance of these as-deposited LCO thin film cathodes is similar to those reported previously. The low capacity is due the disordered crystalline microstructure and sluggish Li ion diffusivity.

The comparison graph in FIG. 36 summarizes the electrochemical performance comparison among typical inorganic thin-film cathodes, along with their annealing temperatures. Most inorganic thin-film cathodes are polycrystalline and undergo high temperature annealing during or after deposition to obtain their electrochemically optimal crystal structure and film texture. In LCO films, for example, annealing above 600° C. leads to a favorable microstructure where the (101)/(104) planes are normal to the substrate, providing efficient ion transport and high discharge capacity. High-temperature annealed LCO exhibits first discharge capacity of 60 μAh/cm²-μm at a current density of 100 μA/cm², and capacity retention above 99.0% is achieved over 1000 cycles under optimal fabrication processing from as reported by the Oak Ridge National Laboratory group (FIG. 36). LCO thin-film cathodes annealed below 500° C. provide a specific capacity of only 54 μAh/cm²-μm and 92.6% capacity retention over 140 cycles at a current density of 10 μA/cm². While the annealing is critical for optimizing performance, it also constrains the substrate materials and increases the number of processing steps in thin film battery fabrication. As-deposited LRCO thin-film cathodes, on the other hand, do not require thermal annealing and present an outstanding specific capacity of 104.2 μAh/cm²-μm and capacity retention of 94.4% over 100 cycles when charged to 3.9 V, outperforming other common inorganic thin-film cathodes presented in FIG. 36. On the other hand, as-deposited LiV₃O₈ can provide first discharge capacity of 133 μAh/cm²-μm at a rate of 10 μA/cm² but a lower capacity retention of 78.8% over 100 cycles. V₂O₅, as a typical as-deposited thin film cathode, exhibits 109 μAh/cm²-μm with a current density of 5 μA/cm² but relative to LRCO, a lower capacity retention of 90.5% is achieved over 100 cycles. Furthermore, V₂O₅ cathodes are naturally unlithiated and as such are incompatible with anode-free cell designs. As-deposited LRCO cathodes, therefore, provide a compelling combination of specific capacity and reversibility (capacity retention).

### Demonstration of Flexible TFBs

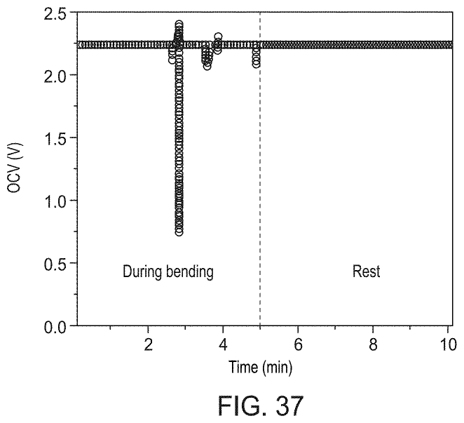

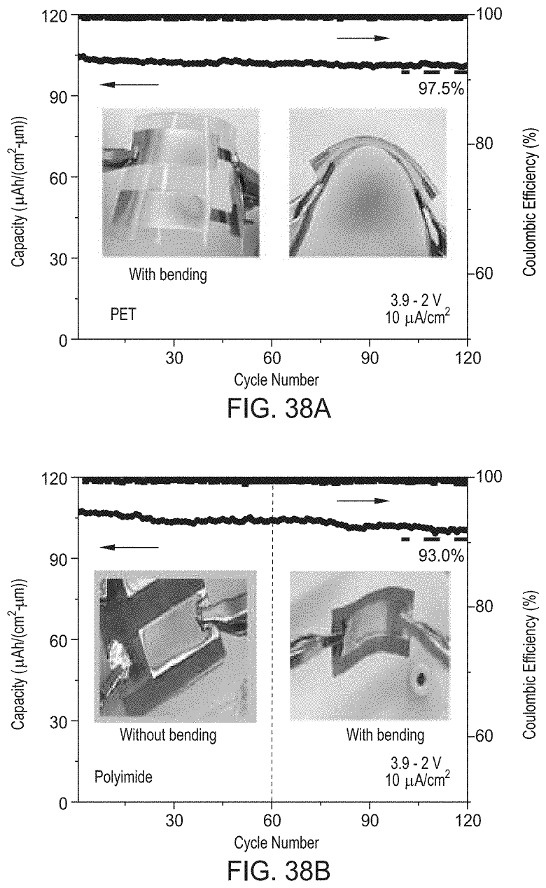

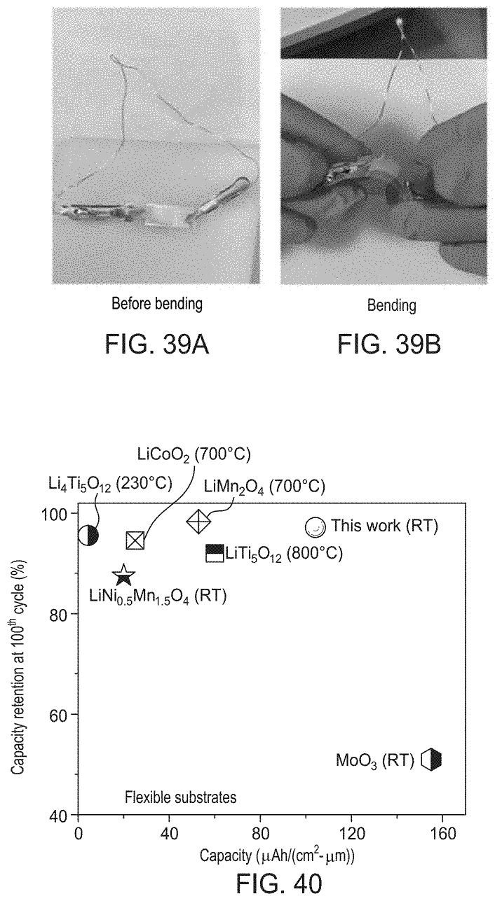

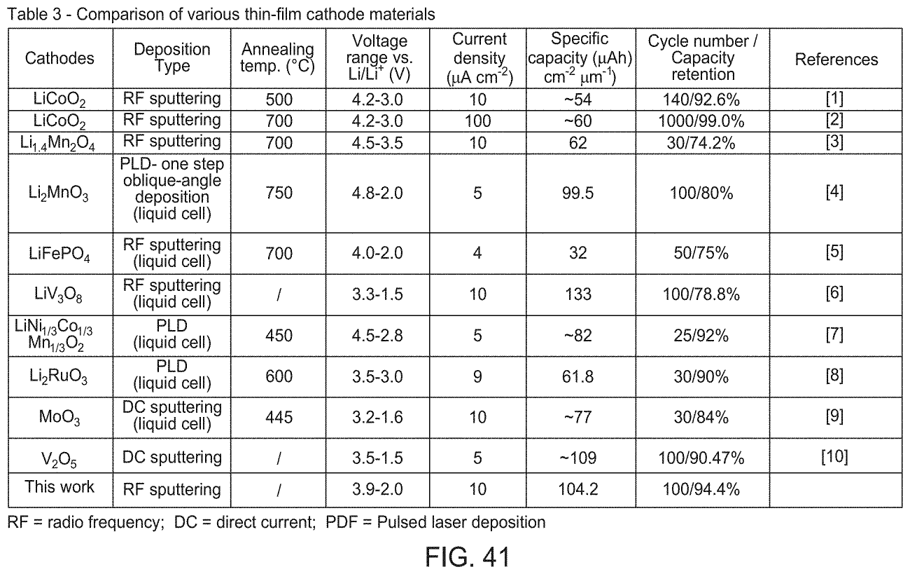

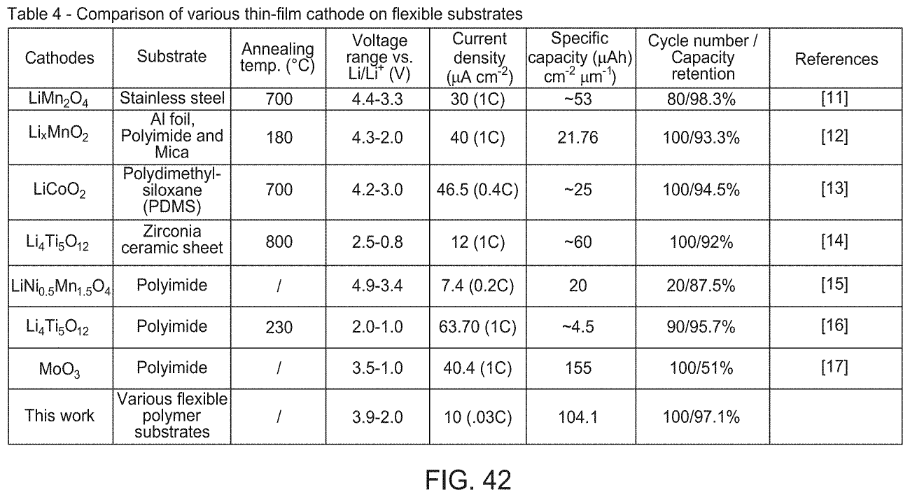

By possessing a high specific capacity in the as-deposited, nanocrystalline morphology, LRCO extends the range of compatible substrates for thin film batteries. Beyond typical rigid, inorganic substrates such as silicon, quartz, and alumina, low cost and flexible thermoplastic substrates can be used as substrates. This has been demonstrated using polyethylene terephthalate (PET) and polyimide (Kapton®) films as substrates. FIG. 38A shows the cycling performance of thin film batteries fabricated on PET substrates. With curvature imposed on the PET throughout the cycling process, LRCO provides a discharge capacity of 101.5 μAh/cm²-μm and capacity retention of 97.5% over 120 cycles. To further demonstrate the stability and flexibility of these batteries on flexible substrates, the same battery (after 120 cycles) was used to power a micro-LED. The TFB successfully powers the LED in a flat (FIG. 39A) or bent conformation (FIG. 39B), demonstrating the versatility of the LRCO materials for many applications. The continual operation of the LED as a function of various bending angles and open-circuit voltage evolution under bending and rest is depicted in FIG. 37.

As another attractive option, Kapton® films can be employed over a much wider temperature range (−250 to 400° C.). Kapton® films were also employed as substrate layers to further demonstrate the outstanding flexibility and mechanical stability of as-deposited LRCO TFB. For an additional comparison of the effect of bending on cell operation, Kapton®-based TFB remained in a flat conformation for the first 60 cycles, and then bent for the subsequent cycles (FIG. 38B). No obvious change in capacity or capacity retention was observed after the first 60 cycles, further proving the flexibility of the battery. A capacity retention of 93.0% was obtained over 120 cycles, which is slightly lower than the 97.5% using PET. Notably, the comparable performance on both substrates and their competitive performance relative to traditional inorganic substrates reinforces the significance of the low temperature preparation of LRCO.

The capacity retention vs. capacity diagram in FIG. 40 represents the electrochemical performance comparison among inorganic thin-film cathodes on flexible substrates. In several examples, high temperature annealing is still employed and those annealing temperatures are included in the plot. High temperature annealing is possible using inorganic substrates, such as stainless steel foils for LiMn₂O₄ (700° C.-annealed) or zirconia sheets for Li₄Ti₅O₁₂ (800° C.-annealed). Another strategy employs film lift-off and transfer processes. LCO deposited on mica and annealed at 700° C. was transferred to flexible polydimethylsiloxane (PMDS) substrates, providing a new fabrication approach yielding reasonable but reduced cathode capacities (25 vs. theoretical capacity of 67 μAh/cm²-μm for LCO). Nevertheless, high temperature annealing limits options for various flexible and low-cost thermoplastic sheets. Fabricated at room temperature onto polyimide substrates, LiNi_{0.5}Mn_{1.5}O₄ provides a reasonable capacity retention of 87.5% after 20 cycles but a limited specific capacity of 20 μAh/cm²-μm. MoO₃ is the only cathode prepared at room temperature where the specific capacity (155 μAh/cm²-μm in the first cycle) is superior to LRCO, but it is compromised by limited capacity retention of 51% after 100 cycles. In comparison, as-deposited LRCO enables simple direct fabrication on flexible thermoplastics substrates (PET and Kapton®) and provides a desirable combination of initial capacity (104.1 μAh/cm²-μm) and high capacity retention of 95.3% over 100 cycles.

The development of a high specific capacity, long cycle life cathode that does not require high temperature post-deposition processing enables multi-cell vertical stack battery configurations. LiPON ionic conductivity is known to substantially degrade above about 350° C. If cathode post-deposition annealing is required, this high temperature processing prevents the sequential deposition of multiple cells into high voltage serial batteries. By employing the unannealed LRCO cathode in the cell design, multiple cells may be sequentially deposited on a single substrate to fabricate multi-cell TFB. Such a design can dramatically reduce the substrate-to-active material mass ratio resulting in overall higher battery specific energy.

### Results

LRCO thin-film cathodes were successfully fabricated and demonstrated in thin film batteries. Increasing the distance between sputtering target and substrate results in deposition of smooth, isotropic films, important for the uniformity of ion transport. XRD suggests the LRCO films are nanocrystalline due to the presence of characteristic LRCO reflections. Oxidation states of 3+ and 4+ for cobalt and ruthenium, respectively, were confirmed by XPS. After fabrication of LRCO TFBs on fused quartz substrates, the highest charge potential was also tested for optimal cycle life. Starting from 3.8 V, the specific capacity and capacity retention increase as charge cut-off potential increases, reaching a maximum of 111.7 μAh/cm²-μm and 94.4% over 100 cycles with a current density of 10 μA/cm² at charge potential of 4 V vs. Li/Li⁺. To avoid structural instability of LRCO at higher potentials, a charge potential of 3.9 V vs. Li/Li⁺ provides a stable compromise between specific capacity and reversibility. Given the low temperature preparation of the as-deposited LRCO, completed thin film batteries were also fabricated directly on flexible plastic substrates without further ex situ annealing. With PET substrates, outstanding specific capacity and capacity retention as high as 101.5 μAh/cm²-μm and 97.5%, respectively, was achieved over 120 cycles. The excellent performance of as-deposited LRCO, substrate versatility, and potential for unannealed multi-cell battery configurations may enable the utilization of TFBs in future flexible applications.

### Conclusions

As discussed herein, the LRCO thin film cathodes are shown to have improved performance when integrated into a solid-state thin film battery. As-deposited amorphous LRCO films have been shown to provide good charge capacity and electrochemical reversibility. Unannealed LRCO has been shown to provide discharge capacities exceeding 110 μAh/cm²-μm, which is almost twice the specific energy of LCO thin-film cathodes. Unannealed LRCO films also provide the ability to develop thin film batteries on flexible/polymeric substrates. Improvements in the LRCO energy storage properties are achievable through crystallization. However, annealed films have been shown to exhibit rapid crystalline grain growth and rough particulate film morphologies.

By forgoing the high-temperature annealing associated with conventional lithium battery cathode production, a wide variety of substrate materials can be employed, including substrates made from flexible thermoplastic materials. Lithium batteries that include the flexible-substrate cathodes can be used in conventional battery applications. Lithium batteries that include the flexible-substrate cathodes can also be used in newer applications, such as wearable, flexible consumer electronics, where device flexibility is required. The novel, flexible cathode materials disclosed herein will enable the development of flexible electronic devices that require flexibility in the battery component.

The energy density of existing flexible batteries remains low as there are limitations regarding the thickness of the materials and total electrolyte loading. The advent of a high performance flexible thin film battery will accelerate the development of next-generation fully flexible electronic systems in combination with existing flexible components such as display, memory, interactive user interfaces and LED. The flexible batteries disclosed herein exhibit high electrochemical performance and excellent mechanical deformability, by virtue of being provided on flexible, low-melt temperature substrates.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

While the foregoing is directed to embodiments of the present disclosure, other and further embodiments of the disclosure may be devised without departing from the basic scope thereof, and the scope thereof is determined by the claims that follow.

### TABLES 3 AND 4 REFERENCES

[1] C. Navone, S. Tintignac, J. Pereira-Ramos, R. Baddour-Hadjean, R. Salot, Solid State Ionics, 192 (2011) 343-346.
[2] B. Wang, J. Bates, F. Hart, B. Sales, R. Zuhr, J. Robertson, J. Electrochem. Soc., 143 (1996) 3203.
[3] S. Das, I. R. Fachini, S. Majumder, R. Katiyar, J. Power Sources, 158 (2006) 518-523.
[4] Z. Qi, J. Tang, J. Huang, D. Zemlyanov, V. G. Pol, H. Wang, ACS Appl. Energy Mater., 2 (2019) 3461-3468.
[5] V. Sugiawati, F. Vacandio, C. Perrin-Pellegrino, A. Galeyeva, A. Kurbatov, T. Djenizian, Scientific reports, 9 (2019) 1-12.
[6] Q. Shi, R. Hu, L. Ouyang, M. Zeng, M. Zhu, Electrochem. Commun., 11 (2009) 2169-2172.
[7] J. Deng, L. Xi, L. Wang, Z. Wang, C. Chung, X. Han, H. Zhou, J. Power Sources, 217 (2012) 491-497.
[8] S. Taminato, M. Hirayama, K. Suzuki, K. Kim, Y. Zheng, K. Tamura, R. Kanno, J. Mater. Chem. A, 2 (2014) 17875-17882.
[9] C. Ramana, V. Atuchin, H. Groult, C. Julien, Journal of Vacuum Science & Technology A: Vacuum, Surfaces, and Films, 30 (2012) 04D105.
[10] J. Bates, N. Dudney, D. Lubben, G. Gruzalski, B. Kwak, X. Yu, R. Zuhr, J. Power Sources, 54 (1995) 58-62.
[11] Q. Xia, S. Sun, J. Xu, F. Zan, J. Yue, Q. Zhang, L. Gu, H. Xia, Small, 14 (2018) 1804149.
[12] Q. Xia, Q. Zhang, S. Sun, F. Hussain, C. Zhang, X. Zhu, F. Meng, K. Liu, H. Geng, J. Xu, Advanced Materials, 33 (2021) 2003524.
[13] M. Koo, K.-I. Park, S. H. Lee, M. Suh, D. Y. Jeon, J. W. Choi, K. Kang, K. J. Lee, Nano letters, 12 (2012) 4810-4816.
[14] A. Sepulveda, J. Speulmanns, P. M. Vereecken, Science and Technology of advanced MaTerialS, 19 (2018) 454-464.
[15] H. Yim, S.-H. Yu, S. H. Baek, Y.-E. Sung, J.-W. Choi, Journal of Power Sources, 455 (2020) 227978.
[16] M. Gockeln, J. Glenneberg, M. Busse, S. Pokhrel, L. Madler, R. Kun, Nano Energy, 49 (2018) 564-573.
[17] J. Glenneberg, G. Kasiri, I. Bardenhagen, F. La Mantia, M. Busse, R. Kun, Nano Energy, 57 (2019) 549-557.

1. An energy storage device, comprising:
a cathode comprising an anion redox active material, the anion redox active material comprising one or more of lithiated ruthenium oxide and lithiated iridium oxide as well as one or more lithium metal oxides, wherein the lithium metal oxide comprises one or more of iron, cobalt, nickel, manganese, tin, titanium, palladium, silver, zinc, gallium, indium, and vanadium;
an anode disposed adjacent to the cathode; and
an electrolyte disposed between the cathode and the anode.

2. The energy storage device of claim 1, wherein the lithium metal oxide comprises one or more of iron, cobalt, nickel, manganese, tin, titanium, and vanadium.

3. The energy storage device of claim 2, wherein the anion redox active material comprises lithiated ruthenium oxide and the lithium metal oxide is a lithium cobalt oxide.

4. The energy storage device of claim 1, wherein the electrolyte has an electrolyte thickness of about 0.05 μm to about 3 μm.

5. The energy storage device of claim 4, further comprising a current collector, wherein the cathode is disposed between the current collector and the electrolyte.

6. The energy storage device of claim 1, wherein the cathode is amorphous or nanocrystalline.

7. The energy storage device of claim 1, wherein the cathode is deposited using PVD.

8. The energy storage device of claim 3, wherein an atomic ratio of lithium to ruthenium is about 5:1 to about 2:1.

9. The energy storage device of claim 3, wherein an atomic ratio of lithium to cobalt is about 21:1 to about 5:1.

10. The energy storage device of claim 3, wherein an atomic ratio of ruthenium to cobalt is about 10:1 to about 1:1.

11. An energy storage device, comprising:
a support substrate;
a platinum film disposed on a portion of the support substrate;
a cathode disposed on the platinum film and comprising lithium, ruthenium, cobalt, and oxygen;
an anode disposed adjacent to the cathode comprising lithium; and
an electrolyte disposed between the cathode and the anode.

12. The energy storage device of claim 11, wherein the electrolyte is a solid lithium-ion conductor.

13. The energy storage device of claim 11, wherein an atomic ratio of ruthenium to cobalt within the cathode is about 10:1 to about 1:1.

14. A method of forming an energy storage device, comprising:
depositing a cathode film onto a support substrate within a process volume of a processing chamber, the cathode film comprising lithium, ruthenium, cobalt, and oxygen;
depositing an electrolyte over the cathode film; and
depositing an anode over the electrolyte.

15. The method of claim 14, wherein during the depositing the cathode film, the support substrate is separated from a sputtering target within the processing chamber by a sputtering distance of about 5 cm to about 20 cm.

16. The method of claim 14, wherein during the depositing of the cathode film, a process temperature within the process chamber is less than about 700° C.

17. The method of claim 14, wherein the cathode film is deposited using physical vapor deposition and a sputtering target is disposed opposite the support substrate, the sputtering target comprising lithium, ruthenium, cobalt, and oxygen.

18. The method of claim 14, wherein an atomic ratio of ruthenium to cobalt within the cathode film is about 10:1 to about 1:1.

19. The method of claim 18, wherein the cathode film has a cathode thickness ranging from about 50 nm to about 40,000 nm.

20. The method of claim 14, wherein the anode is a lithium anode and the electrolyte is a solid lithium-ion conductor.
